(19) United States
(12) Patent Application Publication
(10) Pub. No.: US 2025/0172612 A1
(43) Pub. Date: May 29, 2025

(54) TEST ARRANGEMENT FOR OVER-THE-AIR TESTING AN ANGLED DEVICE UNDER TEST IN A DEVICE-UNDER-TEST SOCKET

(71) Applicant: Advantest Corporation, Tokyo (JP)

(72) Inventors: José MOREIRA, Stuttgart (DE); Hiromitsu TAKASU, Tokyo (JP); Natsuki SHIOTA, Tokyo (JP); Aritomo KIKUCHI, Tokyo (JP); Yasuyuki KATO, Tokyo (JP); Hiroyuki MINEO, Tokyo (JP)

(21) Appl. No.: 19/038,974

(22) Filed: Jan. 28, 2025

Related U.S. Application Data
(63) Continuation of application No. PCT/EP2023/059652, filed on Apr. 13, 2023.

(30) Foreign Application Priority Data
Jul. 29, 2022 (EP) 22 187 978.6

(51) Int. Cl. G01R 31/319; G01R 1/04; G01R 29/10; G01R 31/28

(52) U.S. Cl. CPC G01R 31/31905; G01R 1/045; G01R 29/10; G01R 31/2896

(57) ABSTRACT

A test arrangement for over-the-air testing an angled device under test is described, wherein the test arrangement has a carrier structure, wherein the test arrangement has a device-under-test socket which is coupled to the carrier structure, wherein the device-under-test socket is configured to establish an electrical contact with an inner surface of the angled device under test or with a connector which is arranged on the inner surface of the angled device under test.

### CROSS-REFERENCE TO RELATED APPLICATIONS

This application is a continuation of copending International Application No. PCT/EP2023/059652, filed Apr. 13, 2023, which is incorporated herein by reference in its entirety, and additionally claims priority from European Application No. 22187978.6, filed Jul. 29, 2022, which is also incorporated herein by reference in its entirety.

### TECHNICAL FIELD

Embodiments according to the invention relate to a test arrangement for over-the-air testing, in particular using a device-under-test socket.

Embodiments according to the invention relate to a socket for over the air testing of L-shaped antenna in Package modules with automated test equipment.

### BACKGROUND OF THE INVENTION

Test arrangements can be used to test devices under test (e.g., an antenna in package device) that are capable of receiving and/or emitting electromagnetic radiation. Commonly the device under test has a flat shape with two opposite surfaces such that, for example, the device under test can be mounted in a device-under-test socket (e.g., an over the air (OTA) socket for radiating near field testing of antenna-in-package devices) such that one of the surfaces faces the device-under-test socket and the other surface faces away from the device-under-test socket. For example, one may orient the device under test such that a surface of the device under test with an antenna faces away from the device-under-test socket.

However, the shape of the device under test may not be planar. For example, the device under test may have an angular shape such as an L-shape. Furthermore, an angled device may be configured to emit and/or receive electromagnetic radiation at at least one outer surface. For example, an angular shaped device under test may have one or more antenna arrays (or other antennas) on one or two outer surfaces. As a result, the angular device under test may have a connector and/or die on an inner surface, which is commonly a less accessible surface.

An angled device under test poses challenges in regards to coupling to a socket, electrical contacting with a socket, and orientation of the device under test, which can all affect testing efficiency, accuracy and reproducibility.

Therefore, there is a need for a test arrangement that improves a compromise between testing efficiency, accuracy and reproducibility.

### SUMMARY

An embodiment may have a test arrangement for over-the-air testing an angled device under test, wherein the test arrangement has a carrier structure; wherein the test arrangement has a device-under-test socket which is coupled to the carrier structure, wherein the device-under-test socket is configured to establish an electrical contact with an inner surface of the angled device under test or with a connector which is arranged on the inner surface of the angled device under test.

Another embodiment may have a test arrangement for over-the-air testing an angled device under test, wherein the test arrangement has a carrier structure; wherein the test arrangement has a device-under-test socket which is coupled to the carrier structure, wherein the device-under-test socket is configured to establish an electrical contact with an inner surface of the angled device under test or with a connector which is arranged on the inner surface of the angled device under test, and wherein the device-under-test socket is configured to position the angled device-under-test
such that a first outer surface of the angled device under test is spaced apart from a surface of the loadboard, and
such that a surface normal of the first outer surface of the angled device-under-test is parallel, within a tolerance of +/−15 degrees, to the surface of the loadboard, and
such that a second outer surface of the angled device under test is facing away from the loadboard, and
such that a surface normal of the second outer surface of the angled device-under-test is perpendicular, within a tolerance of +/−15 degrees, to the surface of the loadboard.

An embodiment of the invention is directed at a test arrangement for over-the-air testing an angled (e.g. L-shaped) device under test (e.g. a L-shape Antenna-in-package device under test), wherein the test arrangement comprises a carrier structure (e.g. a PCB test fixture or a loadboard), wherein the test arrangement comprises a device-under-test socket which is coupled to the carrier structure (e.g. the PCB test fixture or the load board) (e.g. directly or with an extender assembly and/or a PCB interposer in between the carrier structure and the device-under-test socket), wherein the device-under-test socket is configured to establish an electrical contact with an inner surface of the angled (e.g. L-shaped) device under test (e.g. with an inner surface of the angled device under test which is opposite to a second outer surface of the angled device under test) or with a connector which is arranged on the inner surface of the angled (e.g. L-shaped) device under test.

The device-under-test socket allows coupling the angled device under test with the test arrangement. Furthermore, the electrical contact allows transmission (unidirectional or bidirectional) of at least one of electrical power, one or more control signals, a measurement signal, or signals between the test arrangement and the device under test coupled to the device-under-test socket. Since the electrical contact is established with the inner surface of the angled device under test, outer surfaces can be arranged to face away from the device-under-test socket. Such an orientation allows testing the angled device under test by itself (e.g., testing its energy consumption during emission or interaction between antenna arrays of the angled device under test) and also allows testing the angled device using one or more external antenna structures (e.g. using a measurement antenna which wirelessly receives a signal transmitted by the angled device under test, and/or using a test antenna which transmits a signal that is wirelessly received by the angled device under test). The design of the device-under-test socket allows advantageously arranging one or more antenna arrays (or one or more other antennas, such as one or more single antennas), which are included on one more of the outer surfaces of the angled device under test, relative to such one or more external antenna structures (e.g. one or more test antenna structures). As a result, the one or more external antenna structures (e.g., for testing one or more antennas or antenna arrays of the device under test, or one or more transmit paths of the device under test, or one or more receive paths of the device under test) can be arranged such that the angled antenna device is between the device-under-test socket and the one or more external antenna structures. Furthermore, the outer surfaces of the angled device under test can therefore be mechanically contacted in order to hold the angled device under test coupled to the device-under-test socket (e.g. by pressing the angled device under test into the device under test socket).

According to an embodiment, the device-under-test socket is configured to position the angled device-under-test such that a first outer surface of the angled (e.g. L-shaped) device under test (e.g. a surface comprising a radiating structure) is spaced apart from a surface (e.g. a main surface) of the carrier structure (e.g., of the loadboard), and such that a surface normal of the first outer surface of the angled (e.g. L-shaped) device-under-test is parallel, within a tolerance of +/−15 degrees, to the surface (e.g. main surface) of the carrier structure (e.g., of the loadboard).

It has been recognized that the design of the device under test socket allows to carry a device under test such that a surface normal of the first outer surface of the device under test may be substantially parallel to the surface of the carrier structure. Consequently one or more antennas, or an antenna array, that may be arranged on the first outer surface of the device under test can have a transmission direction (e.g., of a main lobe) which is at least substantially parallel to the surface of the carrier structure. As a result, a position of an antenna structure (e.g. of a test antenna for testing the device under test) can be selected along the surface of the carrier structure. Such a placement of the antenna structure (e.g. of the test antenna) can be mechanically advantageous, since the carrier structure may serve as a carrier for the antenna structure. For example, the surface of the carrier structure can be used as a guide for determining a position and/or an orientation of the antenna structure.

Since the first outer surface is arranged spaced apart from the surface of the carrier, interaction with a carrier surface (e.g. a surface of the carrier structure) can be reduced or eliminated, such as short circuiting, reflection, and interferences.

According to an embodiment, the device-under-test socket is configured to position the angled device-under-test such that a second outer surface of the angled (e.g. L-shaped) device under test (e.g. a surface comprising a radiating structure) is facing away from the carrier structure, and such that a surface normal of the second outer surface of the angled (e.g. L-shaped) device-under-test is perpendicular, within a tolerance of +/−15 degrees, to the surface of the carrier structure (e.g., of the loadboard).

Such a design of the device-under-test socket allows for an efficient testing of devices under test comprising antenna structures on two outer surfaces. It has been recognized that the design of the device under test socket allows to carry a device under test such that a surface normal of the second outer surface of the device under test may be substantially perpendicular to the surface of the carrier structure. Consequently one or more antennas, or an antenna array, that may be arranged on the second outer surface of the device under test can have a transmission direction (e.g., of a main lobe) which is at least substantially perpendicular to the surface of the carrier structure. However, it has been recognized it is possible with reasonable effort to place an external antenna (e.g. a test antenna) in such a manner that it is well aligned to the antenna structure on the second outer surface of the device under test.

Moreover, it has been recognized that the above mentioned design of the device under test socket allows applying a force onto the second outer surface (e.g., for holding the angled device under test) that is orientated at least essentially perpendicular to the surface of the carrier structure.

According to an embodiment, an area of the carrier structure (e.g. loadboard) which is adjacent (e.g. with spacing in between) to the first outer surface of the angled device-under-test (e.g. an area of the carrier structure, e.g. loadboard, which is adjacent to projection of an outward (outbound) surface normal of the first outer surface of the angled device under test onto the loadboard) is free from power planes and/or free from ground planes. The adjacent area may be arranged in a half space through the device-under-test socket or device under test that comprises the first outer surface. The adjacent area may be adjacent (e.g. with a spacing in between) to the first outer surface of the angled device-under-test (e.g. in an area which is adjacent to a projection of an outward (outbound) surface normal of the first outer surface of the angled device under test onto the carrier structure, e.g. loadboard)

It has been recognized that power planes and/or ground planes can negatively impact reception and/or transmission of electromagnetic radiation by the device under test (e.g., beam forming). Since the adjacent area is free from power planes and/or free from ground planes, the effect on the electromagnetic radiation may be reduced and accuracy of the testing of the angled device under may be improved (e.g. in the case that an antenna structure is arranged on the first outer surface).

According to an embodiment, an area of the carrier structure (e.g. loadboard) which is adjacent (e.g. with a spacing in between) to the first outer surface of the angled device-under test (e.g. an area of the carrier structure, e.g. loadboard, which is adjacent to a projection of an outward (outbound) surface normal of the first outer surface of the angled device under test onto the carrier structure, e.g. loadboard) is free from metallization.

It has been recognized that metallization of the adjacent area can negatively impact transmission and/or reception of electromagnetic radiation (e.g., beam forming), e.g., in the case that an antenna structure is arranged on the first outer surface. Since the adjacent area is free from metallization, the effect on the electromagnetic radiation may be reduced and accuracy of the testing of the angled device under may be improved.

According to an embodiment, an absorber material is arranged on the carrier structure (e.g. loadboard) in an area which is adjacent (e.g. with a spacing in between) to the first outer surface of the angled device-under-test (e.g. in an area which is adjacent to a projection of an outward (outbound) surface normal of the first outer surface of the angled device under test onto the carrier structure, e.g. loadboard). The absorber material may comprise a radio frequency absorber material (e.g., rubberized foam material impregnated with carbon and/or iron).

The absorber material reduces reflection and/or interferences. As a result, accuracy of the testing of the angled device under may be improved, e.g. in the case that an antenna structure is arranged on the first outer surface.

According to an embodiment, the device-under-test socket is configured to position the angled device-under-test such that a spacing between the first outer surface of the angled device under test and the carrier structure (e.g. loadboard) is at least 2 wavelengths (e.g. free-space wavelengths, or wavelengths in a medium between the first outer surface of the angled device under test and the carrier structure) at a lowest frequency of operation of the angled device under test (e.g. at a lowest frequency of operation of an Antenna-in-Package (AiP) module that makes up the device under test or that is included in the device under test).

It has been recognized effects on emission and/or reception (e.g., beamforming, reflections, formation of standing waves, and interferences) of one or more antenna arrays that may be arranged on the first outer surface and that may be caused by the carrier structure are significantly reduced at such distance.

According to an embodiment, the device-under-test socket is attached to (e.g. arranged on) a daughter board, which is mounted to the carrier structure (e.g. test fixture PCB or load board), with a spacing between the daughter board and the load board (e.g., wherein the spacing between the daughter board and the load board is, for example, provided using a stiffener, and, wherein, for example, an electrical connection between the daughter board and the load board is provided using an electrical connector (e.g. using an array connector for digital/power signals and optionally also for IF RF signals).

A daughter board allows easier upgrading of older testing arrangement and changing between different device-under-test sockets by using different daughter boards. Furthermore, the spacing between the daughter board and the load board establishes a spacing between the angled device under test and the carrier structure (e.g., of at least two wavelengths at a lowest frequency of operation of the angled device under test). For example, the spacing can be established particularly reliable by using a stiffener. The daughterboard can further support electrical wiring, auxiliary circuits and connectors. For example, the daughterboard may support a coaxial connector that may be electrically connected to the device-under-test socket for enabling an electrical connection to the device under test when coupled to the device-under-test socket.

According to an embodiment, the test arrangement comprises a first antenna or antenna structure (e.g. a single aperture antenna (e.g. dual linear polarized or circular polarized)) configured to receive a signal radiated from the first outer surface of the angled device under test and/or configured to emit a signal to be received at the first outer surface of the angled device.

The first antenna or antenna device allows establishing an over the air connection with a device under test in the device-under-test socket. Therefore, the first antenna or antenna structure allows testing the device under test. The device-under-test socket allows orienting the device under test in a defined way such that the first antenna or antenna structure can be accurately oriented relative to the angled device under test (or such that an accurate alignment between the first antenna or antenna structure and the angled device under test can be achieved).

According to an embodiment, the test arrangement comprises a first antenna or antenna structure (e.g. a single aperture antenna (e.g. dual linear polarized or circular polarized)), wherein an aperture of the first antenna or antenna structure is arranged at a distance from the first outer surface of the angled device under test, such that a surface normal of the first outer surface of the angled device under test extends through the aperture of the first antenna or antenna structure (e.g., at least when the second antenna or antenna structure is placed at an operation position).

The first outer surface may have or be configured to emit and/or receive (e.g., by beamforming) a main lobe in a direction perpendicular to the first outer surface. By arranging the surface normal of the first outer surface through the aperture of the first antenna or antenna structure (or, in other words, by placing the first antenna such that the surface normal extends through the aperture of the first antenna), reception and/or emission of the first antenna or antenna structure may be improved and a good electromagnetic coupling between the first antenna or antenna structure and an antenna of the device under test can be achieved.

According to an embodiment, the first antenna or antenna structure is mounted to have a fixed position with respect to the device-under-test socket.

Such a fixed position allows repeated coupling and testing of a plurality of angled device under tests, wherein accuracy and reproducibility of the testing may be improved. Moreover, it should be noted that using the mentioned arrangement, the first antenna or antenna structure may, in some cases, not be in a handler path and consequently does not need to be removed when the device under test is exchanged by a handler.

According to an embodiment, the first antenna or antenna structure (or a second antenna or antenna structure) is mechanically attached to an arm of a handler (e.g., which is configured to insert the angled device under test into the device-under-test socket), such that the first antenna or antenna structure (or the second antenna or antenna structure) is moveable.

The arm allows the first antenna or antenna structure (or the second antenna or antenna structure) to be movable, which enables removal of the first antenna or antenna structure (or of the second antenna or antenna structure) (e.g., for easier coupling of the angled device under test to the device-under-test socket) or readjustment of the first antenna or antenna structures (or if the second antenna or antenna structure). In the case of the handler being configured to insert the angled device under test into the device-under-test socket, the handler may facilitate coupling and positioning the first antenna or antenna structure (or of the second antenna or antenna astructure) during or after coupling of the angled device under test to the device-under-test socket.

According to an embodiment, the first antenna or antenna structure (or the second antenna or antenna structure) is configured to be connected with a signal source and/or with a signal receiver via a blind-mating microwave connection (e.g. via a blind mating waveguide connection) when the handler has placed the first antenna or antenna structure (or the second antenna or antenna structure) in an operating position (or, equivalently, when the handler has inserted the angled device under test into the test socket, or when the handler pushes the device under test into the test socket).

The signal source and/or a signal receiver enables the first antenna or antenna structure (or the second antenna or antenna structure) to emit a signal (e.g., to be received by an antenna or antenna array of the angled device under test) and/or to receive a signal (e.g., emitted by an antenna or antenna array of the angled device under test), and therefore facilitates testing of the angled device under test. The blind-mating microwave connection facilitates (e.g., manual and/or automatic) coupling between the signal source and/or a signal receiver and the first antenna or antenna structure (or between the signal source and/or a signal receiver and the second antenna or antenna structure).

According to an embodiment, the test arrangement comprises a second antenna or antenna structure (e.g. a single aperture antenna (e.g. dual linear polarized or circular polarized)) configured to receive a signal radiated from the second outer surface of the angled device under test and/or to emit a signal to be received at the second outer surface of the angled device under test (e.g., at least when the second antenna or antenna structure is placed at an operation position) (e.g., or, equivalently, when the handler has inserted the angled device under test into the test socket, or when the handler pushes the device under test into the test socket).

The second antenna or antenna structure allows testing an antenna structure on the second outer surface and/or the device under test. The second antenna or antenna structure benefits from an orientation of the second outer surface defined by the device-under-test socket. The first and second antenna or antenna structure allow to test the device under test using signals emitted by and/or received by the first and second outer surface (e.g., simultaneously or successively) without having to recouple the angled device under test at a different orientation (e.g., or at a different device-under-test socket).

According to an embodiment, the test arrangement comprises a second antenna or antenna structure (e.g. a single aperture antenna (e.g. dual linear polarized or circular polarized)), wherein an aperture of the second antenna or antenna structure is arranged at a distance from the second outer surface of the angled device under test such that a surface normal of the second outer surface of the angled device under test extends through the aperture of the second antenna or antenna structure (e.g., at least when the second antenna or antenna structure is placed at an operation position) (e.g., or, equivalently, when the handler has inserted the angled device under test into the test socket, or when the handler pushes the device under test into the test socket).

The second outer surface may have or be configured to emit and/or receive (e.g., by beamforming) a main lobe in a direction perpendicular to the second outer surface. By arranging the surface normal of the second outer surface through the aperture of the second antenna or antenna structure (or, in other words, by placing the second antenna such that the surface normal extends through the aperture of the second antenna), reception and/or emission of the second antenna or antenna structure may be improved and a good electromagnetic coupling between the second antenna or antenna structure and an antenna of the device under test can be achieved.

According to an embodiment, the second antenna or antenna structure is mechanically attached to an arm of a handler (e.g., which is configured to insert the angled device under test into the device-under-test socket), such that the second antenna or antenna structure is moveable. The first and second antennas or antenna structures may, for example, be attached to the same/common arm or may each be attached an individual arm.

The arm allows the second antenna or antenna structure to be movable, which enables removal of the second antenna or antenna structures (e.g., for easier insertion/coupling of the angled device under test to the device-under-test socket) or readjustment of the second antenna or antenna structures. In the case of the handler being configured to insert the angled device under test into the device-under-test socket, the handler facilitates coupling and positioning the first antenna or antenna structure during coupling of the angled device under test to the device-under-test socket. In case of a common arm, the first and second antenna structures may be arranged in a pre-determined orientation for facilitating orientating the first and second antenna structures relative to the first and second outer surfaces. In case of separate arms, customized orientations of the first and second antenna structures are enabled.

According to an embodiment, the second antenna or antenna structure is part of a pusher for pushing the angled device under test into the device-under-test socket, or the second antenna or antenna structure is configured to be moveable together with a pusher for pushing the angled device under test into the device-under-test socket (wherein, for example, the pusher is arranged such that the pusher, or a part of the pusher, is in between the second antenna or antenna structure and the second outer surface of the angled device under test when the device under test in inserted into the device-under-test socket) (and/or wherein, for example, the pusher is arranged such that the pusher, or a part of the pusher, is in between the first antenna and the first outer surface of the angled device under test when the angled device under test is inserted into the device-under-test socket).

The second antenna or antenna structure is movable with the pusher and can therefore be moved (e.g., for easier coupling of the angled device under test to the device-under-test socket) or readjusted (e.g., by adapting an orientation thereof). Since the pusher is configured to push the angled device under test into the device-under-test socket, the pusher facilitates coupling and positioning the second antenna or antenna structure during coupling of the angled device under test to the device-under-test socket.

According to an embodiment, the second antenna or antenna structure is configured to be connected with a signal source and/or with a signal receiver via a blind-mating microwave connection (e.g. via a blind mating waveguide connection) when the handler has placed the second antenna or antenna structure in an operating position (e.g., or, equivalently, when the handler has inserted the angled device under test into the test socket, or when the handler pushes the device under test into the test socket).

The connection with the signal source and/or with the signal receiver enables the second antenna or antenna structure to emit a signal (e.g., to be received by an antenna or antenna array of the angled device under test) and/or to receive a signal (e.g., emitted by an antenna or antenna array of the angled device under test), and therefore facilitates testing of the angled device under test. The blind-mating microwave connection may facilitate (e.g., manual and/or automatic) coupling between the signal source and/or a signal receiver and the second antenna or antenna structure.

According to an embodiment, the device-under-test socket comprises an angled recess or an angled exemption, configured to support and/or align the angled device under test. The angled recess or the angled exemption may have a sidewall on one or both of its ends.

The angled recess or the angled exemption has two (or more) abutment surfaces (e.g., at an angle) that can abut against the first and second inner surface respectively. Such abutment surfaces may realize (at least partly) a pre-determined orientation and/or position of the angled device under test. A pre-determined orientation and/or position of the angled device under test may facilitate establishing an electrical connection and improve reproducibility and accuracy of testing. The optional one or more sidewalls may further limit lateral movement of the angled device under test.

According to an embodiment, the device-under-test socket is arranged such that a second inner surface of the angled device under test, which is opposite to the second outer surface of the angled device under test, is spaced from the carrier structure (e.g. loadboard) by at least 10 mm, or by at least 30 mm, or by at least 45 mm or by at least 2 wavelengths or by at least 3 wavelengths or by at least by 4 wavelengths (e.g. free-space wavelengths, or wavelengths in a medium between the first outer surface of the angled device under test and the carrier structure) at a lowest frequency of operation of the angled device under test (e.g. at a lowest frequency of operation of an Antenna-in-Package (AiP) module that makes up the device under test or that is included in the device under test) (e.g., and such that, advantgeously, an edge of the first outer surface is spaced from the loadboard by at least 10 mm, or by at least 20 mm or by at least 2 wavelengths or by at least 3 wavelengths or by at least by 4 wavelengths, e.g. free-space wavelengths, or wavelengths in a medium between the first outer surface of the angled device under test and the carrier structure, at a lowest frequency of operation of the angled device under test, e.g. at a lowest frequency of operation of an Antenna-in-Package (AiP) module that makes up the device under test or that is included in the device under test).

It has been recognized that such a spacing significantly reduces effects (e.g., reflection, beamforming, and interferences) of the carrier structure onto characteristics of one or more antenna structures of the device under test, or, generally speaking, onto circuitry (e.g., antenna structures, circuitry for signal transmission, or a silicon die for conversion of signals such as conversion of intermediate frequency signals to mmWave signals and vice versa) on the second inner surface and/or the second outer surface.

According to an embodiment, the device-under-test socket comprises a socket height of at least 10 mm, or of at least 30 mm, or of at least 45 mm, such that a second inner surface of the angled device under test, which is opposite to the second outer surface of the angled device under test, is spaced from the carrier structure (e.g., loadboard) by at least 10 mm, or by at least 30 mm, or by at least 45 mm or by at least 2 wavelengths or by at least 3 wavelengths or by at least by 4 wavelengths (e.g. free-space wavelengths, or wavelengths in a medium between the first outer surface of the angled device under test and the carrier structure) at a lowest frequency of operation of the angled device under test (e.g. at a lowest frequency of operation of an Antenna-in-Package (AiP) module that makes up the device under test or that is included in the device under test) (e.g., and such that, advantgeously, an edge of the first outer surface is spaced from the loadboard by at least 10 mm, or by at least 20 mm or by at least 2 wavelengths or by at least 3 wavelengths or by at least by 4 wavelengths, e.g. free-space wavelengths, or wavelengths in a medium between the first outer surface of the angled device under test and the carrier structure, at a lowest frequency of operation of the angled device under test, e.g. at a lowest frequency of operation of an Antenna-in-Package (AiP) module that makes up the device under test or that is included in the device under test).

It has been recognized that such a spacing significantly reduces effects (e.g., reflection, beamforming, and interferences) of the carrier structure onto characteristics of one or more antenna structures of the device under test, or, generally speaking, onto circuitry (e.g., antenna structures, circuitry for signal transmission, or a silicon die for conversion of signals such as conversion of intermediate frequency signals to mmWave signals and vice versa) on the second inner surface and/or the second outer surface.

According to an embodiment, the device-under-test socket comprises one or more coaxial pogo pins (which may, for example, extend from a lower surface of the device-under-test socket which is in contact with the load board, to an upper surface of the device-under-test socket, which is in contact with the second inner surface of the angled device under test), in order to establish an electrical connection between the carrier structure (e.g., loadboard) and the angled device under test (wherein, for example, a first end of the coaxial pogo pin may be in contact with a pad on the load board, and wherein, for example, a second end of the coaxial pogo pin may be in contact with a pad on the angled device under test).

Pogo pins are commonly depressible and allow the device-under-test socket to establish a reliable electrical contact with the device under test upon the device under test being coupled to the device-under-test socket (e.g., when being pushed by a handler/pusher into the device-under-test socket). For example, the coaxial springs enable a high frequency interconnect to the device-under-test socket.

According to an embodiment, an extender structure (e.g. comprising an extender and a PCB interposer) is arranged between the carrier structure (e.g. the loadboard or the PCB test fixture) and the device-under-test socket.

The extender allows separation of the functions of establishing an electrical connection to the device under test and realizing a space between the carrier structure and the device under test. Therefore, for example, the same device-under-test socket can be used in combination with a plurality of extenders having a different height. Structures (or circuitry) for establishing the electrical contact with the device under test can mostly or entirely be realized in the device-under-test socket, allowing for a simpler design of the extender. The optional PCB interposer may, for example, allow for a rerouting between different geometries of electrical contacts of the device-under-test socket and the extender.

According to an embodiment, the extender structure comprises an extender assembly,
wherein the extender assembly comprises one or more coaxial pogo pins (which may, for example, extend from a lower surface of the extender assembly which is in contact with the carrier structure, e.g. load board, to an upper surface of the extender assembly, which is in contact with a PCB interposer or with the device-under-test socket), in order to establish an electrical connection between the carrier structure (e.g. loadboard) and the angled device under test (wherein, for example, a first end of the coaxial pogo pin may be in contact with a pad on the load board, and wherein, for example, a second end of the coaxial pogo pin may be in contact with a pad on the PCB interposer, which is in between the extender assembly and the device-under-test socket).

The extender assembly provides a spacing between the device-under-test socket and the carrier structure, wherein the coaxial pogo pins provide electrical contacts that may cover a distance across the space provided by the extender. The coaxial pogo pins furthermore provide an electrical interface compatible with a device-under-test socket configured to receive the device under test being pushed inside, improving the compatibility with other/older carrier structures.

According to an embodiment, the test arrangement comprises at least two device-under-test sockets configured to carry respective angled devices under test (e.g. two equal devices under test), wherein the at least two device-under-test sockets are arranged (e.g. back-to-back) to position respective angled devices under test such that respective first outer surfaces of the respective angled devices under test are aligned in opposite (averted) directions.

A test arrangement with at least two device-under-test sockets allows testing more than one device under test at once (e.g., simultaneously or successively; e.g. within one cycle of a handler placing the devices under test in the device under test sockets). Furthermore, with the respective first outer surfaces of the respective angled devices under test being aligned in opposite (averted) directions, interferences between signals emitted by and/or received at the respective first outer surfaces are reduced.

According to an embodiment, the test arrangement comprises at least two rows (e.g. parallel rows) of device-under-test sockets, wherein the device-under-test sockets are configured to carry respective angled devices under test, wherein the at least two rows of device-under-test sockets are arranged (e.g. back-to-back; e.g. with sides of the device-under-test sockets where the first outer surfaces of the devices under test are located, averted with respect to each other) to position respective angled devices under test such that respective first outer surfaces of the respective angled devices under test are aligned in opposite (averted) directions.

Such an arrangement improves a compromise between arranging a plurality of devices under test in an increased density and reducing interferences between signals emitted by and/or received at the respective first outer surfaces.

According to an embodiment, a test arrangement for over-the-air testing an angled (e.g. L-shaped) device under test (e.g. a L-shape Antenna-in-package device under test), comprises a carrier structure (e.g. a PCB test fixture or a loadboard). The test arrangement also comprises a device-under-test socket which is coupled to the carrier structure (e.g. the PCB test fixture or the load board) (e.g. directly or with an extender assembly and/or a PCB interposer in between the carrier structure and the device-under-test socket), wherein the device-under-test socket is configured to establish an electrical contact with an inner surface of the angled (e.g. L-shaped) device under test (e.g. with an inner surface of the angled device under test which is opposite to a second outer surface of the angled device under test) or with a connector which is arranged on the inner surface of the angled (e.g. L-shaped) device under test, and wherein the device-under-test socket is configured to position the angled device-under-test such that a first outer surface of the angled (e.g. L-shaped) device under test (e.g. a surface comprising a radiating structure) is spaced apart from a surface (e.g. a main surface) of the loadboard, and such that a surface normal of the first outer surface of the angled (e.g. L-shaped) device-under-test is parallel, within a tolerance of +/−15 degrees, to the surface (e.g. main surface) of the loadboard, and such that a second outer surface of the angled (e.g. L-shaped) device under test (e.g. a surface comprising a radiating structure) is facing away from the loadboard, and such that a surface normal of the second outer surface of the angled (e.g. L-shaped) device-under-test is perpendicular, within a tolerance of +/−15 degrees, to the surface of the loadboard.

It has been recognized that such an arrangement of the first and second outer surfaces improves a compromise between accessibility of antenna structures for testing and reducing influences of the surface of the carrier structure.

### BRIEF DESCRIPTION OF THE DRAWINGS

The drawings are not necessarily to scale, emphasis instead generally being placed upon illustrating the principles of the invention. In the following description, various embodiments of the invention are described with reference to the following drawings, in which:

FIG. 1 shows a schematic cross section of a test arrangement for over-the-air testing an angled device under test;

FIG. 2A shows a schematic cross section through a first example of an angled device under test;

FIG. 2B shows a schematic cross section through a second example of an angled device under test;

FIG. 3 shows a perspective view of an angled device under test;

FIG. 4 shows a result of a simulation of a far field emitted by an antenna element of a first antenna array of a first outer surface of the device under test depicted in FIG. 3;

FIG. 5 shows a perspective view of an angled device under test;

FIG. 6 shows a result of a simulation of a far field emitted by an antenna element of a first antenna array of a first outer surface antenna array of the device under test depicted in FIG. 5;

FIG. 7 shows a schematic cross sectional view of another example of the test arrangement with a device under test;

FIG. 8 shows a perspective view of an example of a device-under-test socket;

FIG. 9 shows a schematic cross sectional view of another example of a test arrangement with a device under test;

FIG. 10 shows schematic cross sectional view of another example of a test arrangement with a device under test;

FIG. 11 shows a schematic top view of an another example of a test arrangement with a plurality of devices under test;

FIG. 12 shows a schematic top view of an another example of a test arrangement with a plurality of devices under test;

FIG. 13A shows a perspective view of an example of a device under test; and

FIG. 13B shows a perspective view of the device under test depicted in FIG. 13A.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may optionally be combined with each other, unless specifically noted otherwise.

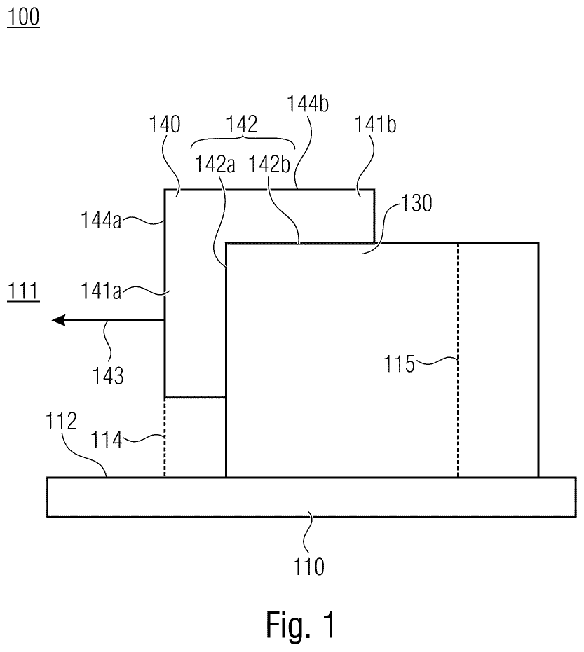

FIG. 1 shows a schematic cross section of a test arrangement 100 for over-the-air testing an angled device under test 140. The test arrangement 100 comprises a carrier structure 110 and a device-under-test socket 130 coupled to the carrier structure 110. The device-under-test socket 130 is configured to establish an electrical contact with an inner surface 142 of the angled device under test 140 or with a connector (not shown in FIG. 1) which is arranged on the inner surface 142 of the angled device under test 140.

The carrier structure 110 may be a printed circuit board (PCB) test fixture or a loadboard. The carrier structure 110 may, for example, be or comprise at least one region with a flat surface. The device-under-test-socket 130 may be arranged on top of the carrier structure 110 (e.g., on the flat surface) or may be coupled to the carrier structure 110 via one or more intermediate devices or structures. An area of the carrier structure 110 (e.g. loadboard) which is adjacent (e.g. with spacing in between) to the first outer surface 144a of the angled device-under-test 140 is free from power planes and/or free from ground planes. The area may be in a half space that is separated by a plane through the device-under-test socket 130 or the device under test 140 (e.g., defined by the first outer surface 144a or first inner surface 142a when the device under test is coupled to the device-under-test socket 130), e.g., in FIG. 1 a space 111 to the left of the first outer surface 144a or first inner surface 142a. The area may be of an area of the carrier structure 110, e.g. loadboard, which is adjacent to projection of an outward (outbound) surface normal 143 of the first outer surface 144a of the angled device under test onto the loadboard. The adjacent area may be adjacent (e.g. with a spacing 114 in between) to the first outer surface of the angled device-under-test 140 (e.g. in an area which is adjacent to a projection of an outward (out-bound) surface normal 143 of the first outer surface 144a of the angled device under test 140 onto the carrier structure 110, e.g. loadboard).

The test arrangement 100 shown in FIG. 1 can, for example, be used to test the angled device under test 140 itself (e.g., without antenna structures detecting electromagnetic radiation emitted by the angled device under test) or to test the angled device under test 140 in combination with one or more additional antennas. For example, the test arrangement 100 may be used to test a power consumption of the device under test 140 or interferences between antennas of the device under test 140). Alternatively, the test arrangement 100 may be configured to wirelessly test one or more antenna structures of the device under test.

Since the device-under-test socket 130 is configured to contact an inner surface 142 of the device under test, outer surfaces of the device under test 140 completely (or at least mostly) face away from the device-under-test socket 130 and the carrier 110. Therefore, an effect of the device-under-test socket 130 and/or the carrier structure 110 on a radiation emitted (and/or received) by the outer surfaces of the device under test 140 (and on a testing thereof) is reduced.

The angled device under test 140 may be (or comprise) an Antenna-in-package (AiP) device. The angled device under test 140 may have an L-shape (as indicated abstractly in FIG. 1), e.g., the device under test may be a device with a first plate 141a connected to a second plate 141b, wherein the plates 141a, 141b are angled relative to each other at at least essentially 90 degrees (e.g., within a tolerance of +/−15 degrees). The angled device under test 140 may comprise a first outer surface 144a (e.g., of the first plate 141a) and a second outer surface 144b (e.g., of the second plate 141b), wherein the first and second outer surfaces 144a, b are angled relative to each other at at least essentially 270 degrees (e.g., within a tolerance of +/−15 degrees). The inner surface 142 of the angled device under test 140 may comprise a first inner surface 142a (e.g., of the first plate 141a) and a second inner surface 142b (e.g., of the second plate 141b), wherein the first and second inner surfaces 142a, b are angled relative to each other at at least essentially 90 degrees (e.g., within a tolerance of +/−15 degrees). The first inner surface 142a and the first outer surface 144a may be arranged parallel to each other. The second inner surface 142b and the second outer surface 144b may be arranged parallel to each other.

The device-under-test socket 130 may be configured to position the angled device-under-test 140 such that the second outer surface 144b of the angled device under test 140 is facing away from the carrier structure 110. The device-under-test socket 130 may be configured to position the angled device-under-test 140 such that a surface normal of the second outer surface 144b of the angled device-under-test is perpendicular, within a tolerance of +/−15 degrees, to the surface 112 of the carrier structure 110. The second outer surface 144b may be arranged parallel to the surface 112 of the carrier structure 110.

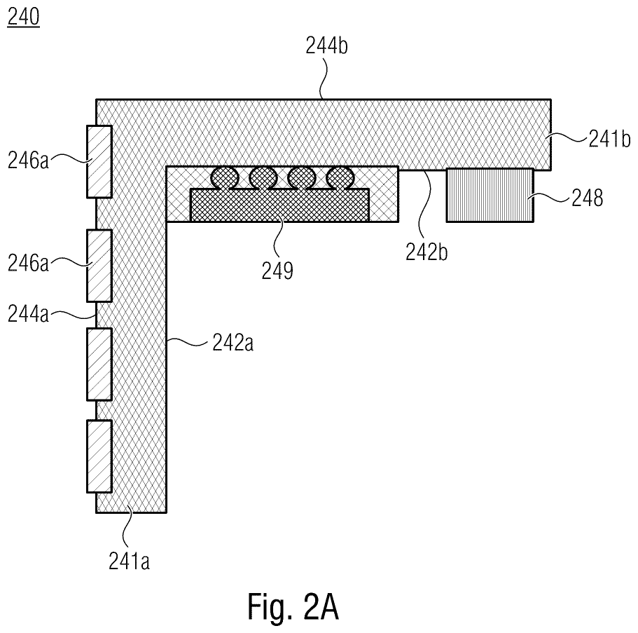

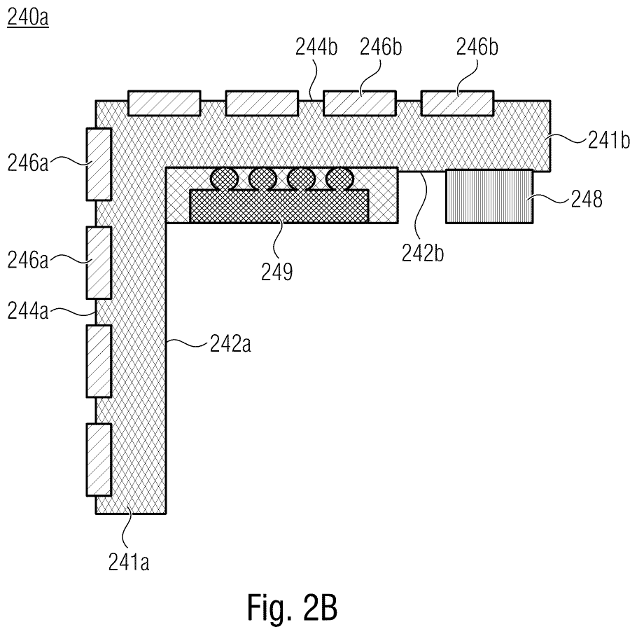

FIG. 2A shows a schematic cross section through a first example of an angled device under test 240, which can take the place of the angled device under test 140.

The device under test 240 comprises a first plate 241a and a second plate 241b, which are angled relative to each other at a 90 degree angle (e.g. within a tolerance of +/−15 degrees). The first plate 241a comprises a first outer surface 244a and a first inner surface 242a and the second plate 241b comprises a second outer surface 244b and a second inner surface 242b.

In the example shown in FIG. 2A the first outer surface 244a comprises a first antenna array 246a with four antenna elements. However, the first outer surface 244a may (additionally or alternatively) comprise any other form of antenna (e.g., a single antenna and/or a circular polarized antenna) and any other number of antenna elements or antenna arrays. Alternatively, the second outer surface 244b may comprise the first antenna array 246a. The first antenna array 246a may be configured to receive and/or transmit electromagnetic radiation.

The device under test 240 may further comprise a connector 248, e.g. an array connector. In the example shown in FIG. 2A, the (array) connector 248 is arranged on the second inner surface 242b. Alternatively, the (array) connector 248 may be arranged on the first inner surface 242a or (e.g., in the case of a plurality of (array) connectors 248) on the first and second inner surface 242a, b. The (array) connector 248 is electrically connected with at least one of the antenna elements (e.g., all of the antenna elements) of the first antenna array 246a. Therefore, an electrical signal applied at the (array) connector 248 may cause the first antenna array 246a to emit electromagnetic radiation. Alternatively or additionally, electromagnetic radiation received by the first antenna array 246a may result in an electric signal at the (array) connector 248. The (array) connector 248 may be or comprise one or more solder balls. The (array) connector 248 may be configured to connect the device under test 140 (e.g., an antenna in package module) to a system (e.g. to a cell phone or to the device-under-test socket 130) and may enable transmission of signals like a power signal, a digital signal, a radio frequency (RF) signal or an intermediate frequency (IF) signal.

The first antenna array 246a may be directly electrically connected with the (array) connector 248 or may be indirectly coupled with the (array) connector 248, e.g. with further electrical components in between. For example, the further electrical components may comprise at least one of an amplifier, a filter, a switch, a resistor, a capacitor, and an integrated circuit. In the example shown in FIG. 2A, the further electrical components comprise an antenna circuitry 249 (e.g., a silicon die). The antenna circuitry 249 may, for example, be configured to convert intermediate frequency (IF) signals into mmWave signals (e.g., of a 5G bandwidth such as in a range of 24 GHz to 53 GHZ) and/or vice versa. Alternatively or additionally, the antenna circuitry 249 may be configured to control (at least partly) beamforming of the first antenna array 246a.

FIG. 2B shows a schematic cross section through a second example of an angled device under test 240a, which can take the place of the angled device under test 140.

The second example of the angled device under test 240a essentially corresponds to the first example of the angled device under test 240 as shown in FIG. 2A, such that identical elements will be designated with identical reference numerals, but further comprises a second antenna array 246b on the second outer surface 244b. The second antenna array 246b may have similar features as the first antenna array 246a. The second antenna array 246b may also be electrically connected to at least one of the (array) connector 248 and the antenna circuitry 249. Alternatively, the second antenna array 246b may be electrically connected to a separate (array) connector and/or to a separate antenna circuitry.

The device-under-test socket 130 may be configured to position the angled device-under-test 140 (e.g. the angled device under test 240 or the angled device under test 240a) such that the first outer surface 144a of the angled device under test 140 (e.g., the first outer surface 244a) is spaced apart from a surface 112 of the carrier structure 110. FIG. 1 shows exemplarily a first distance 114 (in form of a dashed line), which indicates the space (or spacing) between the first outer surface 144a and the surface 112 of the carrier structure 110. The device-under-test socket 130 may be configured to position the angled device-under-test 140 such that that a surface normal of the first outer surface 144a of the angled device-under-test 140 is parallel (as exemplarily depicted in FIG. 1), e.g. within a tolerance of +/−15 degrees, to the surface 112 of the carrier structure 110. The first outer surface 144a may be arranged perpendicular to the surface 112 of the carrier structure 110.

The device-under-test socket 130 may be configured to position the angled device-under-test 140 such that a spacing (e.g., the first distance 114) between the first outer surface 144a of the angled device under test 140 and the carrier structure 110 (e.g., the surface 112 thereof) is at least two wavelengths at a lowest frequency of operation of the angled device under test. The angled device under test 140 may be operated in a frequency band of the 5G standard, for example within the range of 24 GHz to 53 GHZ (e.g., the frequency range 2). In such a case, the lowest frequency of operation may be 24 GHz with a wavelength of 12.5 mm. The space between the first our surface 144a and the surface 112 of the carrier structure 110 may, for example, be 25 mm or larger (i.e. two times 12.5 mm).

The spacing may be defined by a different surface of the device under test 140. The device-under-test 130 socket may be arranged such that the second inner surface 142b of the angled device under test 140 (e.g. the second inner surface 242b of the angled device under test 240), which is opposite to the second outer surface 114b of the angled device under test 140, is spaced from the carrier structure 110 (e.g., from the surface 112) by at least 10 mm, or by at least 30 mm, or by at least 45 mm or by at least 2 wavelengths or by at least 3 wavelengths or by at least by 4 wavelengths at a lowest frequency of operation of the angled device under test.

The device-under-test socket 130 may comprise a socket height 115 (indicated as a dashed imaginary line) of at least 10 mm, or of at least 30 mm, or of at least 45 mm, such that the second inner surface 142b of the angled device under test 140, which is opposite to the second outer surface 144b of the angled device under test 140, is spaced from the carrier structure by at least 10 mm, or by at least 30 mm, or by at least 45 mm or by at least 2 wavelengths or by at least 3 wavelengths or by at least by 4 wave-lengths at a lowest frequency of operation of the angled device under test.

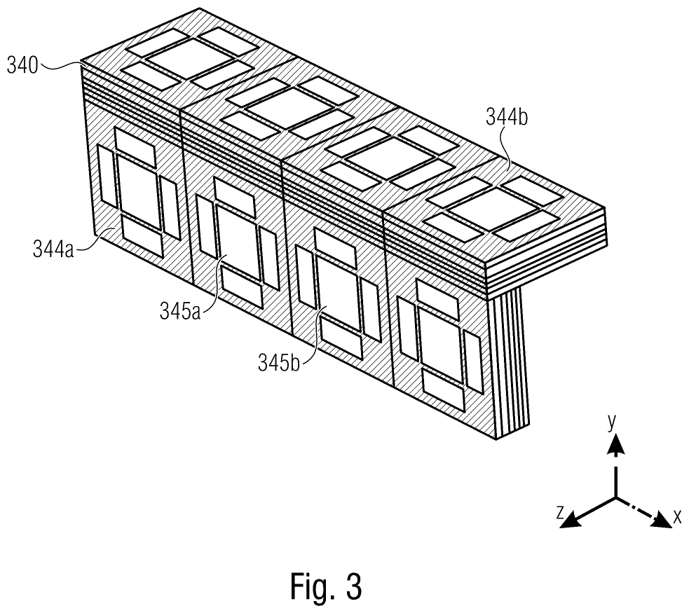

FIG. 3 shows a perspective view of an angled device under test 340, which can take the place of the angled device under test 140.

The device under test 340 comprises a first outer surface 344a having a first antenna array with four antenna elements and a second outer surface 344b having a second antenna array with four antenna elements. At least one antenna element may comprise at least one parasitic patch. In the example shown in FIG. 3, each antenna element has four parasitic patches surrounding a center antenna structure. The first outer surface 344a comprises two central antenna element 345a, b. There is not metalized surface in the vicinity of the device under test 340.

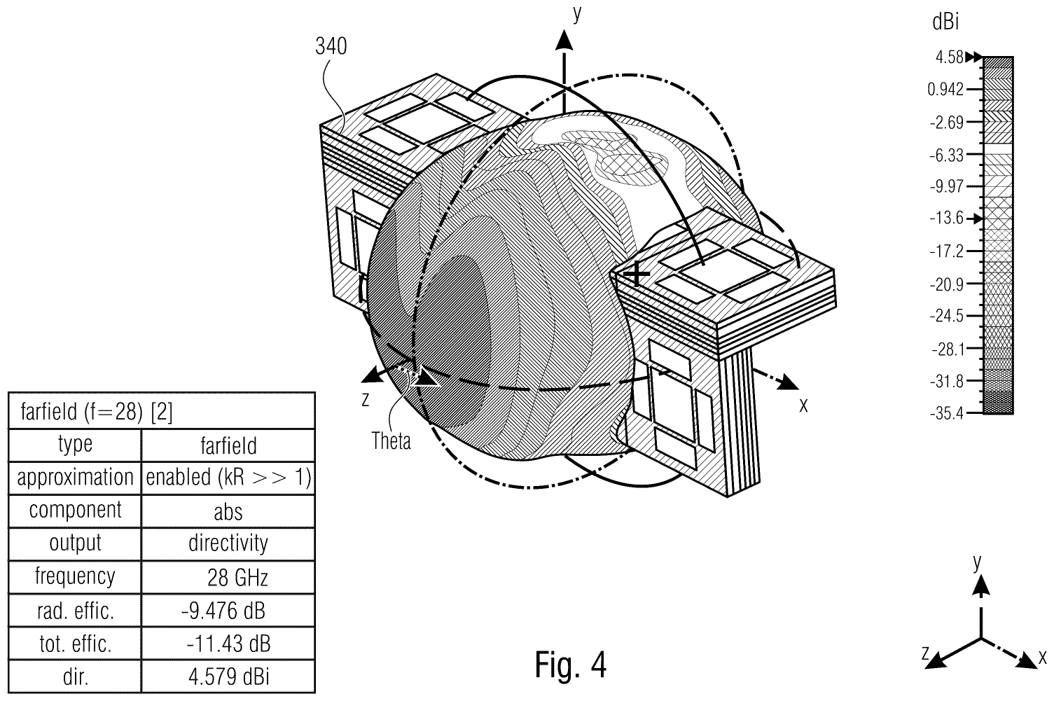

FIG. 4 shows a result of a simulation of a far field emitted by an antenna element (e.g., by antenna element 345a or 345b) of the first antenna array of the first outer surface 344a of the device under test 340 depicted in FIG. 3. It is noted that for the sake of simplicity, the simulation of the far field depicted in FIG. 3 originates from a center of the first antenna array of the first outer surface 344a (e.g., between the central antenna elements 345a, b). However, the simulation of the far field may have an at least essentially identical shape when originating from a center of one of the central antenna elements 345a, b. The far field shows pronounced lobes oriented perpendicular to the antenna elements 345a and 345b of the first outer surface 344a (wherein, however, a radiation in a backward direction may be reduced or suppressed when the device under test 340 is applied in a system, e.g., in a system providing a metallized backplane).

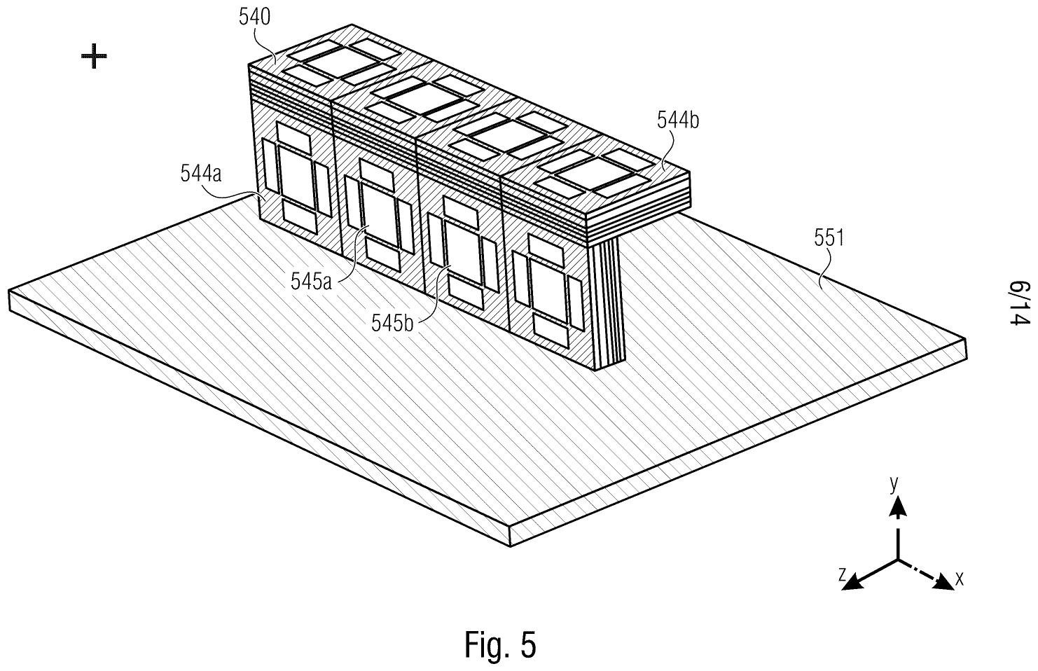

FIG. 5 shows a perspective view of an angled device under test 540, which can take the place of the angled device under test 140. The device under test 540 comprises a first outer surface 544a comprising a first antenna array with four antenna elements and a second outer surface 544b comprising a second antenna array with four antenna elements. The first antenna array of the first outer surface 544 a comprises two central antenna elements 545a, b. There is metal (e.g., copper) surface 551 in a distance of 2 mm away from the first outer surface 544a.

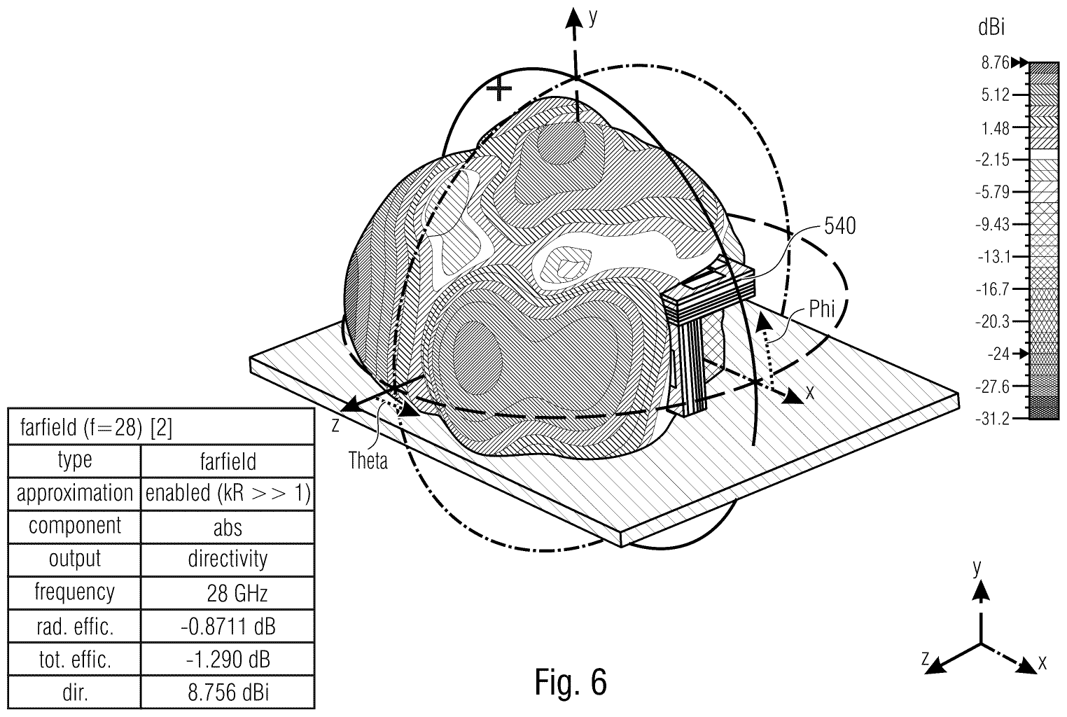

FIG. 6 shows a result of a simulation of a far field emitted by an antenna element (e.g., by antenna element 545a or 545b) of the first antenna array of the first outer surface antenna array 544a of the device under test 530 depicted in FIG. 5 (advantgeously taking into consideration the metal surface 551). Compared to the result depicted in FIG. 4, the far field shows less pronounced radiation oriented perpendicular to the two antenna elements of the first outer surface antenna array 544a. Instead, the intensity of the far field is distributed more evenly around the device under test 540, with separate mainlobes in two directions which are different from a direction of a surface normal onto the first outer surface 544a. The result shows that a metalized surface in a close vicinity can affect the far field emitted by the device under test 540 and therefore reduce the accuracy and/or reproducibility of the test. For example, a metalized surface may reduce a spatial selectivity of a beamforming antenna array and/or change the direction of the mainlobe(s).

Therefore, a spacing such as described above (e.g., at least two wavelengths, or at least 10 mm, or of at least 30 mm, or of at least 45 mm) can improve the accuracy and/or reproducibility of the test.

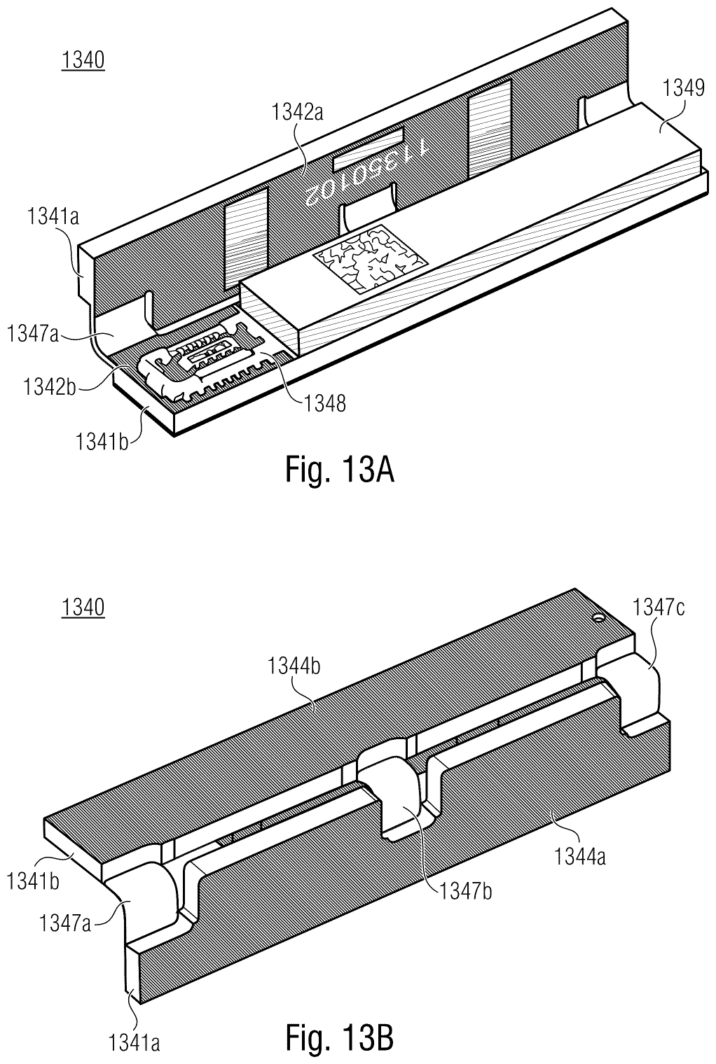

FIG. 13A shows a perspective view of an example of a device under test 1340, which can take the place of the angled device under test 140.

The device under test 1340 comprises a first inner surface 1342a and a second inner surface 1342b. In the example shown in FIG. 13A, the device under test comprises a first plate 1341a having the first inner surface 1342a and a second plate 1341b having the second inner surface 1342b. The first and second plate 1341a, b are mechanically (and optionally electrically) connected by flexible conducting structures, such as three flexible printed circuits 1347a,b,c. The first and second plate 1341a, b may be movable (e.g., bendable) relative to each other, e.g., in order to facilitate manufacturing or assembly in a system). However, the movability of the plates may, in some cases, facilitate a coupling to the device-under-test socket, but may also complicate testing in some cases. Alternatively, the first and second plate 1341a, b may be arranged fixedly relative to each other.

The device under test 1340 comprises a connector1348 (e.g. an array connector) and a silicon die 1349 (or any other antenna circuitry) on the second inner surface 1342b. The silicon die 1349 may be electrically contacted indirectly via the array connector 1348 or directly via electrical contacts of the silicon die 1349 itself (not shown in FIG. 13A). The device-under-test socket described herein is configured to establish an electrical contact with the inner surface of the device under test 1340 such as the (array) connector 1348 on the second inner surface 1342b.

FIG. 13B shows another perspective view of the device under test 1340 depicted in FIG. 13A. The device under test 1340 comprises a first outer surface 1344a (on the first plate 1341a) and a second outer surface 1344b (on the second plate 1341b). The first and second outer surfaces 1344a, b are configured (e.g. by formation of respective antenna structures) to emit and/or receive electromagnetic radiation. To this end, antenna elements (e.g., antenna arrays) may be arranged at least partly on the first and/or second surface 1344a, b or may be arranged at least partly within the first and/or second plate 1341a, b. In the example shown in FIG. 13B, the first and second outer surface 1344a, b are configured to emit and/or receive electromagnetic radiation. Alternatively, only the first or only the second outer surface 1344a, b may be configured to emit and/or receive electromagnetic radiation.

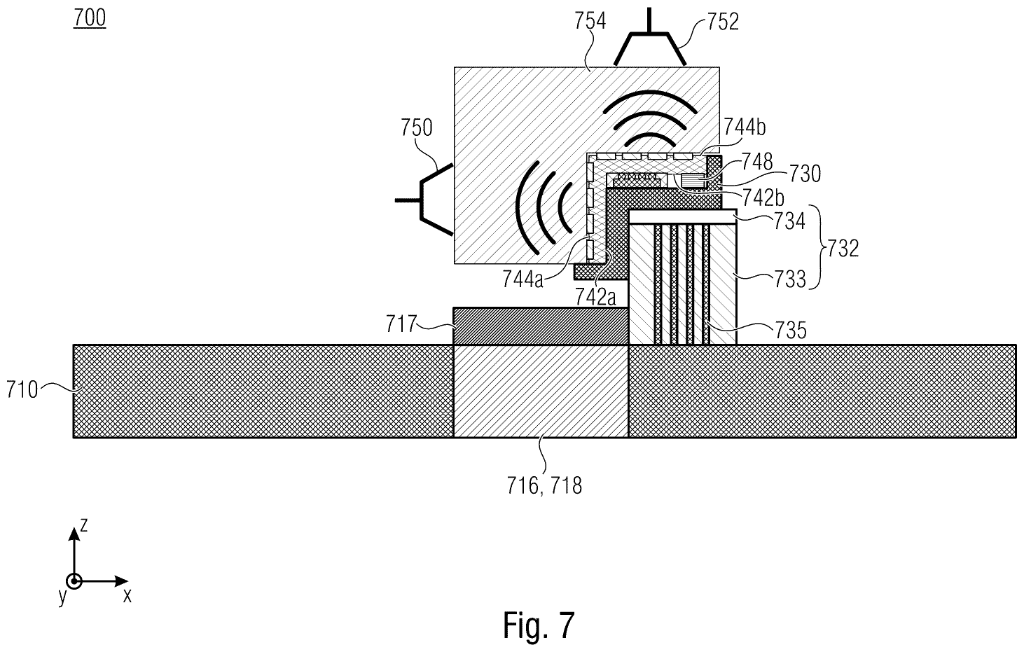

FIG. 7 shows a schematic cross sectional view of another example of the test arrangement 700 with a device under test 740. The device under test 740 comprises a first inner surface 742a, a second inner surface 742b, a first outer surface 744a, and a second outers surface 744b. The test arrangement comprises a carrier structure 710 (e.g., a loadbard). The device under test 740 may be any device under test described herein. The test arrangement 700 comprises a device-under-test socket 730, which may be any device-under-test socket described herein.

The test arrangement 700 may comprise an extender structure 732 that is arranged between the carrier structure 710 (e.g. the loadboard or the PCB test fixture) and the device-under-test socket 730. The extender structure 732 may comprise an extender 733 and a PCB interposer 734. The extender forms a structure allowing the device-under-test socket 730 to be arranged elevated relative to the carrier structure 710 (e.g. spaced from the carrier structure 710). The extender 733 may be configured to receive the device-under-test socket 730 directly or indirectly, e.g., via the PCB interposer 734 and/or other components. The PCB interposer may be configured to form an adapter (e.g., structurally and/or in regards to locations of electrical connections) between the extender 733 and the device-under-test socket 730. For example, the PCB interposer 734 may allow for a rerouting between different geometries of electrical contacts of the device-under-test socket 730 and the extender 733, increasing compatibility there between. The PCB interposer 734 may, for example, (optionally) comprise one or more decoupling capacitors.

In the example shown in FIG. 7, the extender structure 732 comprises an extender assembly 735, wherein the extender assembly comprises one or more coaxial pogo pins 735, in order to establish an electrical connection between the carrier structure (e.g. loadboard) and the angled device under test (wherein, for example, a first end of the coaxial pogo pin may be in contact with a pad on the load board, and wherein, for example, a second end of the coaxial pogo pin may be in contact with a pad on the PCB interposer, which is in between the extender assembly and the device-under-test socket). The coaxial pogo pins may (as exemplarily depicted in FIG. 7) extend from a lower surface of the extender assembly 735 which is in contact with the carrier structure 710, e.g. load board, to an upper surface of the extender assembly 735, which is in contact with a PCB interposer 734 or with the device-under-test socket 730. In the example shown in FIG. 7, the extender structure 732 has four coaxial pogo pins, however any other number of coaxial pogo pins may be provided. At least one of the coaxial pogo pins may be depressible by the PCB interposer 734 and/or the device-under-test socket 730. The extender assembly 735 may have a larger height (e.g., in a direction perpendicular to the surface of the carrier structure 710) than the device-under-test socket 730.

In the following, it will be discussed how the characteristics of the test arrangement can be improved by designing different spatial regions. For example, a so-called “adjacent area” can be designed to be free from power planes or ground planes. Alternatively or in addition, a so-called “first designated region” can be designed to be completely free from metallization.

An adjacent area 716 of the carrier structure 710 (e.g. loadboard), which is adjacent (e.g. with spacing in between) to the first outer surface 744a of the angled device-under-test 740 (e.g. an area of the carrier structure 710, e.g. loadboard, which is adjacent to projection of an outward (outbound) surface normal of the first outer surface 744a of the angled device under test 740 onto the carrier structure 710 or loadboard) is free from power planes and/or free from ground planes. The adjacent area may be arranged in a half space through the device-under-test socket 730 that comprises the first outer surface 734a. The adjacent area may be adjacent (e.g. with a spacing in between) to the first outer surface 744a of the angled device-under-test 740 (e.g. in an area which is adjacent to a projection of an outward (outbound) surface normal of the first outer surface 744a of the angled device under test 740 onto the carrier structure 710, e.g. loadboard). In the example shown in FIG. 7, the adjacent area 716 is a rectangular area bordering a surface of the extender 733 facing the first inner surface 742a. However, the adjacent area may have any other shape (e.g., a triangle, a trapez, a polygon or a ellipsis). Furthermore, the adjacent area may be spaced apart from the extender 733 (e.g., shifted to the left in FIG. 7) or may at least partially surround the extender 733 (e.g., shifted to the right in FIG. 7).

A first designated area 718 of the carrier structure 710 (e.g. loadboard) which is adjacent (e.g. with a spacing in between) to the first outer surface 742a of the angled device-under test 740 is free from metallization. The first designated area 718 of the carrier structure 710, e.g. loadboard, may be adjacent to a projection of an outward (outbound) surface normal of the first outer surface 744a of the angled device under test 740 onto the carrier structure 710, e.g. loadboard). The first designated area 718 may be identical to, intersect with or compromise the adjacent area 716.

The test arrangement 700 may comprise an absorber material 717 that is arranged on the carrier structure 710 (e.g. loadboard) in a second designated area which is adjacent (e.g. with a spacing in between) to the first outer surface 744a of the angled device-under-test 740 (e.g. in a second designated area which is adjacent to a projection of an outward (outbound) surface normal of the first outer surface of the angled device under test onto the carrier structure, e.g. loadboard). The absorber material may comprise a radio frequency absorber material (e.g., rubberized foam material impregnated with carbon and/or iron). The second designated area may be identical to, intersect with or compromise the adjacent area 716 (and/or the first designated area 718). However, the second designated area may advantgeously be neighboring to the so-called “adjacent area 716” of the carrier structure 710. In the example shown in FIG. 7, the absorber material 717 is arranged elevated compared to the surrounding area of the carrier structure 710 (e.g. attached on top of the carrier structure 710). Alternatively, the absorber material 717 may be arranged at least essentially flush with the surrounding area of the carrier structure 710 or recessed therein (e.g. embedded in an opening of the carrier structure).

The device-under-test socket 730 is configured to establish an electrical contact with a connector (e.g. an array connector) 748 of the device under test 740. Alternatively, the device-under-test socket 730 may be configured to establish an electrical contact with at least one of the first and second inner surfaces 742a, b.

The test arrangement 700 shown in FIG. 7 has a first antenna or antenna structure 750 and a second antenna or antenna structure 752. Alternatively, the test arrangement 700 may only comprise the first antenna or antenna structure 750 or only the second antenna or antenna structure 752 (i.e. not a combination of the first and second antenna or antenna structure 750, 752).

The first antenna or antenna structure 750 (e.g. a single aperture antenna (e.g. dual linear polarized or circular polarized)) is configured to receive a signal radiated from the first outer surface 744a of the angled device under test 740 and/or configured to emit a signal to be received at the first outer surface 744a of the angled device 740. To this end, the first antenna or antenna structure 750 is arranged at a distance from the first outer surface 744a of the angled device under test 740, e.g. such that a surface normal of the first outer surface 744a of the angled device under test 740 extends through an aperture of the first antenna or antenna structure 750. The first antenna or antenna structure 750 may be placeable at an operation position. A surface normal of the first outer surface 744a of the angled device under test 740 (which may, for example, be coaxial to a main lobe (e.g., by beamforming) of an antenna structure on the first outer surface, and/or which may extend through a geometric center of one or more antenna arrays of the first outer surface 744a) may extend through the aperture (e.g. through the center of the aperture) of the first antenna or antenna structure 750. The first antenna or antenna structure 750 may be mechanically attached to an arm of a handler (or pusher) 754, such that the first antenna or antenna structure 750 is moveable. The handler 754 may be configured to insert the angled device under test 740 into the device-under-test socket 730.

The first antenna or antenna structure 750 may be configured to be connected with a signal source and/or with a signal receiver (not shown in FIG. 7) via a blind-mating microwave connection (e.g. via a blind mating waveguide connection) when the handler 754 has placed the first antenna or antenna structure 750 in an operating position (or, equivalently, when the handler 754 has inserted the angled device under test 740 into the device-under-test test socket 730, or when the handler 754 pushes the device under test 740 into the device-under-test socket 730). The operation position may be defined by an alignment of a radiation direction of the first outer surface 744a (e.g., perpendicular to the first outer surface 744a) with a receiving direction of the first antenna or antenna structure 750. The signal source and/or the signal receiver may be part of a processing device configured to test the test under device, e.g., using a computer program product comprising instructions that when executed, e.g. by an automated test equipment, cause the processing device to perform at least one of generating signals to be transmitted by the first antenna or antenna structure 750 and processing (e.g., detecting) signals received by the first antenna or antenna structure 750.

The second antenna or antenna structure 752 (e.g. a single aperture antenna (e.g. dual linear polarized or circular polarized)) may be configured to receive a signal radiated from the second outer surface 744b of the angled device under test 740 and/or to emit a signal to be received at the second outer surface 744b of the angled device under test 740 (at least when the second antenna or antenna structure 752 is placed at an operation position) (or, equivalently, when the handler 754 has inserted the angled device under test 744b into the device-under-test socket 730, or when the handler 754 pushes the device under test 740 into the device-under-test socket 730).

An aperture of the second antenna or antenna structure 752 may be arranged at a distance from the second outer surface 744b of the angled device under test 740 such that a surface normal of the second outer surface 744b of the angled device under test 740 extends through the aperture of the second antenna or antenna structure 752 (at least when the second antenna or antenna structure 752 is placed at an operation position) (or, equivalently, when the handler has inserted the angled device under test into the test socket, or when the handler pushes the device under test into the test socket). A surface normal of the second outer surface 744b of the angled device under test 740 coaxial to a main lobe of an antenna structure on the second outer surface, and/or a surface normal extending through a geometric center of one or more antenna arrays of the first outer surface 744a may extend through the aperture of the first antenna or antenna structure 750 (e.g. through a center of the aperture of the first antenna or antenna structure).

The second antenna or antenna structure 752 may be mechanically attached to an arm of the handler (e.g., a pusher) 754, such that the second antenna or antenna structure 752 is moveable.

The second antenna or antenna structure 752 may be part of a pusher 754 for pushing the angled device under test 740 into the device-under-test socket 730, or the second antenna or antenna structure 752 may be configured to be moveable together with a pusher 754 for pushing the angled device under test 740 into the device-under-test socket 730. The pusher 754 may be arranged such that the pusher 754, or a part of the pusher 754, is in between the second antenna or antenna structure 752 and the second outer surface 744b of the angled device under test 740 when the device under test 740 is inserted into the device-under-test socket 730. The pusher 754 may be arranged such that the pusher 754, or a part of the pusher 754, is in between the first antenna or antenna structure 750 and the first outer surface 744a of the angled device under test 740 when the angled device under test 740 is inserted into the device-under-test socket 730. It should be noted that, in some cases, a force to push the device under test may act in two directions, e.g. in order to push both the first inner surface of the device under test and the second inner surface of the device under test towards the device under test socket. Accordingly, the pusher may be angled, to be in (pushing) contact both with the first outer surface of the device under test and with the second outer surface of the device under test. Consequently, the pusher may be moved both in a direction along the surface normal of the first outer surface of the device under test and in a direction along the surface normal of the second outer surface of the device under test.

The second antenna or antenna structure 752 may be configured to be connected with a signal source and/or with a signal receiver (not depicted in FIG. 7) via a blind-mating microwave connection (e.g. via a blind mating waveguide connection) when the handler 754 has placed the second antenna or antenna structure 752 in an operating position (or, equivalently, when the handler 754 has inserted the angled device under test 740 into the device-under-test socket 730, or when the handler 754 pushes the device under test 740 into the device-under-test socket 730). The operation position may be defined by an alignment of a radiation direction of the second outer surface 744b (e.g., perpendicular to the second outer surface 744b) with a receiving direction of the second antenna or antenna structure 752. The signal source and/or the signal receiver may be part of a processing device configured to test the test under device 740, e.g., using a computer program product comprising instructions that when executed, e.g. by an automated test equipment, cause the processing device to perform at least one of generating signals to be emitted by the second antenna or antenna structure 752 and processing (e.g., detecting) signals received by the second antenna or antenna structure 752. The first and second antenna or antenna structure 750, 752 may be configured to be connected to the same signal source and/or signal receiver or to separate signal sources and/or signal receivers. The signal source and/or signal receiver may, for example, be comprised by the test arrangement 700.

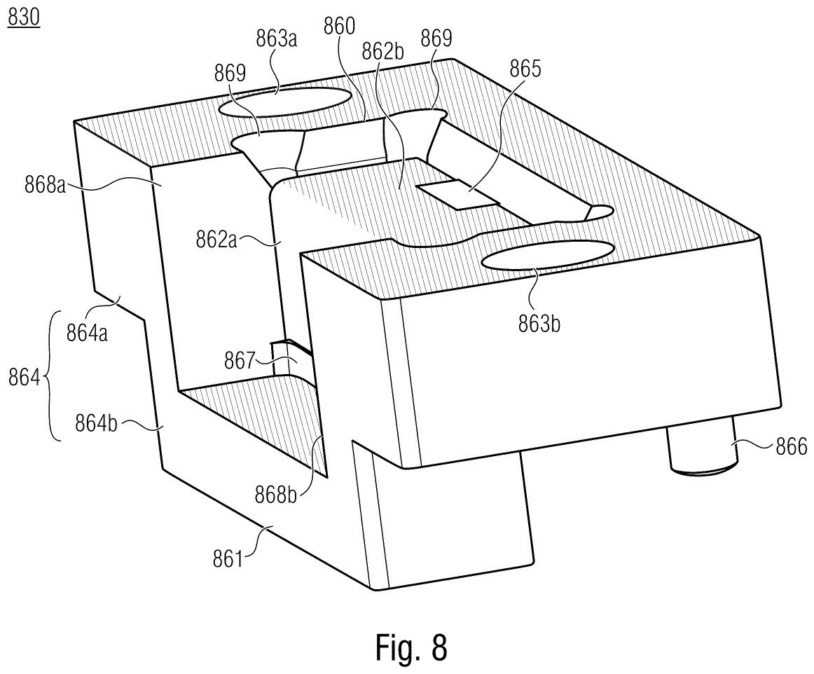

FIG. 8 shows a perspective view of an example of a device-under-test socket 830 which may, for example, be used in any of the embodiments disclosed herein.

The device-under-test socket 830 may be configured to receive any device under test described herein and be part of any test arrangement described herein. The device-under-test socket 830 comprises an angled recess or an angled exemption 860, configured to support and/or align the angled device under test. The angled recess or the angled exemption 860 comprises a first abutment surface 862a configured to abut against the first inner surface of the device under test (e.g., first inner surfaces 142a, 242a, or 742a) and a second abutment surface 862b configured to abut against the second inner surface of the device under test (e.g., second inner surface 142b, 242b, or 742b). The first abutment surface 862a and the second abutment surface 862b may be arranged at an abutment surface angle, wherein a sum of the abutment surface angle (e.g. 270 degree) and of the angle between the first and second inner surface of the device under test (e.g. 90 degree) is at least essentially 360 degrees. For example, if the first and second inner surface of the device under test may be arranged at an angle of 90 degrees, the abutment surface angle may be 270 degrees (with the sum of 90 degrees and 270 degrees being 360 degrees).

Any surface of the device-under-test socket 830 may be configured to establish an electrical contact with the inner surface of the device under test. For example, the first and/or second abutment surface 862a, b may be configured to establish an electrical contact with the inner surface of the device under test, and/or to provide a ground plane for an antenna structure of the device under test. To this end, the first and/or second abutment surface 862a, b may comprise or may be formed of an electrically conducting material (e.g., at least one of gold, cupper, iron, and nickel). Alternatively, the first and/or second abutment surface may comprise, or may be formed of, a dielectric (non-conducting) material (e.g. a wear-resistant material). Optionally, the first and/or second abutment surface 862a, b may comprise one or more (local) socket connectors 865 (or other contacting structures for contacting the device under test, like conductive pads, pogo pins, spring-loaded contacts, or the like). The socket connector 865 is arranged such that when the device under test is arranged in the device-under-test socket 860, the connector 865 establishes an electrical connection with the inner surface of the device under test or a connector thereof (e.g., array connectors 248, 748).

The device-under-test socket 830 comprises a support body 864 comprising a main socket structure 864a and a leg socket structure 864b. The main socket structure 864a and the leg socket structure 864b both have a rectangular cuboid outer shape (optionally with rounded edges), wherein at least two edges of the leg socket structure 864b are smaller (shorter) than two edges (e.g. corresponding edges) of the main socket structure 864a. The main socket structure 864a and the leg socket structure 864b may, for example, have the same height. A side surface 861 of the leg socket structure 864b is arranged flush with a side surface of the main socket structure 864a, and three other side surfaces of the leg socket structure 864b are recessed relative to three other (corresponding) side surfaces of the main socket structure 864a. The leg socket structure 864b may therefore, for example, be received by an opening in the carrier structure or the extender structure such that, for example, lateral movement of the device-under-test socket 830 is limited by side surfaces of the leg socket structure 864b. However, the device-under-test socket may also be attached on top of an extender structure (e.g. on top of the extender structure 732), wherein the main socket structure 864a may be arranged on a top surface of the extender structure, and wherein the leg socket structure 864b may be adjacent to a side wall of the extender structure.

The device-under-test socket 830 may further or alternatively comprise one or more protrusions 866 extending from the support body 864 (e.g., from the main socket structure 864a) in a direction towards the carrier structure. The protrusion 866 may be or comprise a shaft (e.g., with a cylinder shape). The protrusion 866 may be received by a recess of the carrier structure or the extender structure 732.

Alternatively or additionally, the device-under-test socket 830 may comprise one or more through holes configured to receive an attachment element such as a pin or screw.

In the example shown in FIG. 8, the angled recess or the angled exemption 860 extends into the main socket structure 864a and a leg socket structure 864b. Alternatively, the angled recess or the angled exemption 860 may only extend into the main socket structure 864a.

The angled recess or the angled exemption 860 may have a respective sidewall 868a, b at both of its ends (only one of which is directly visible in FIG. 8). The sidewalls 868a, b face each other and are arranged at least essentially parallel to each other (disregarding an optional tapering). In the example shown in FIG. 8, the sidewalls 868a, b are oriented perpendicular or at least approximately perpendicular relative to the first and second abutment surfaces 862a, b. The sidewalls 868a, b may restrict lateral movement of the device under test within the angled recess or the angled exemption860, while still allowing for a smooth and well-guided insertion of the device under test into the angled recess or the angled exemption 860 and also allowing for a smooth extraction of the device under test. Alternatively, the angled recess or the angled exemption860 comprise only one sidewall, e.g., in order to increase flexibility in regards to positioning.

The angled recess or the angled exemption 860 may comprise at least one tapering, e.g., such that a cross section (e.g., parallel to the first or second abutment surface 862a, b) decreases in a direction from outside towards the first or second abutment surface 862b. In the example shown in FIG. 8, the angled recess or the angled exemption 860 comprises a first and a second tapering. According to a first tapering, a distance between the sidewalls 868a, b decreases towards the first abutment surface 862a. According to a second tapering, three sidewalls of the main socket structure 864a that are surrounding the second abutment surface 862b have a cross section that decreases towards the second abutment surface 862b. The tapering may have a self-centering function and facilitate inserting the device under test into the angled recess or the angled exemption 860.

The device-under-test socket 830 may have adjacent openings 869 that intersect the angled recess or the angled exemption 860. In the example shown in FIG. 8, the device-under-test socket 830 comprises four adjacent openings 869 that are arranged next to corners of the second abutment surface 862b. Alternatively, the device-under-test socket 830 may comprise any other number of adjacent openings 869 at any other location that is located adjacent to the second abutment surface 862b (and/or the first abutment surface 862a). For example, the adjacent openings may be adapted to prevent the device under test from canting, e.g. when the device under test is inserted into the socket 830. However, the adjacent openings may also be helpful to retrieve the device under test from the socket 830.

The angled recess or the angled exemption 860 may comprise additional recesses or elevations, e.g., in order to conform to a shape of the device under test. For example, the angled recess or the angled exemption 860 shown in FIG. 8 comprises a step 867 in the first abutment surface 862a. The step 867 may, for example, accommodate to a structural feature of the first inner surface or provide a support surface for the device under test such as to form a space below (e.g., for grabbing the device under test).

The device-under-test socket 830 may comprise a blind mating interface. In the example shown in FIG. 8, the main socket structure 864a comprises two (e.g., blind) mating recesses 863a,b. Alternatively, the main socket structure 864a may comprise any other amount of mating recesses. The mating recesses 863a, b are configured to receive (e.g., blind) mating protrusions of a pusher or handler (e.g., handler 754). Alternatively or additionally the main socket structure 864a may comprise one or more (e.g., blind) mating protrusions, for example, configured to be received by a (e.g., blind) mating recess of the pusher or handler (e.g., handler 754).

To conclude, the socket 830 may receive an angled device under test and may establish an electrical contact with the angled device under test. The device under test may be positioned (aligned) within the angled recess or angled exemption 860, such that an over-the-air test of the device under test is possible using antenna structures or antennas on both outer surfaces of the angled device under test. The device under test is well aligned in the socket, while distortions of radiation characteristics of the antennas or antenna structures of the device under test by the socket can be kept reasonably small. The socket can be easily attached to a carrier structure and can be used in any of the embodiments disclosed herein.

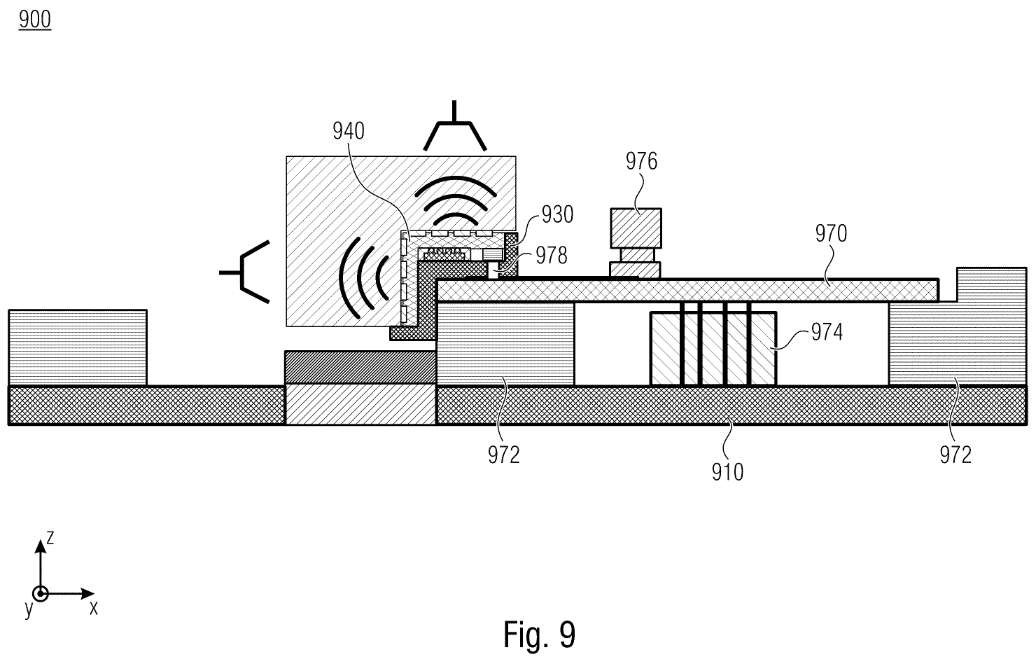

FIG. 9 shows a schematic cross sectional view of another example of a test arrangement 900 with a device under test 940, which may be any device under test described herein. The test arrangement 900 comprises a device-under-test socket 930 that may be any device-under-test socket described herein.

The example shown in FIG. 9 may correspond to the example shown in FIG. 7, except for the fact that a device-under-test socket 930 is attached to a daughter board 970 instead of an extender structure 732. However, the daughter board 970 and the extender structure 732 are not exclusive to each other and may be combined (e.g., an extender structure may be arranged between the daughter board 970 and the carrier structure and/or between the daughter board 970 and the device-under-test socket 930).

The device-under-test socket 930 is attached to (e.g. arranged on) the daughter board 970, which is mounted to the carrier structure 910 (e.g. test fixture PCB or load board), with a spacing between the daughter board 970 and the carrier structure 910. The spacing between the daughter board 970 and the carrier structure 910 may be, for example, provided using one or more stiffeners 972. The stiffener 972 may comprise at least one of a polymer, a resin, a glass, and a metal. The stiffener 972 may comprise one or more stiffener structures. At least one of the stiffener structures may comprise a step (e.g., in order to facilitate arranging the daughter board 970 on the stiffener and/or limit movement in a direction parallel to the surface of the carrier structure 910). The stiffener 972 may comprise one or more structures of at least essentially equal height or with surfaces arranged at at least essentially equal height (e.g., in the case of a stiffener structure with a step).

The stiffener 972 may form or be part of a socket guide. The socket guide may be configured to facilitate arranging the daughter board 970 on the stiffener 972 (e.g., for a user or an automated device).

Alternatively or additionally, an extender structure (e.g., similar to the extender structure 732) may be provided between the carrier structure 910 and the stiffener 972, or between the stiffener 972 and the daughter board 970, or between the carrier structure 910 and the daughter board 970, or between the daughter board 970 and the device-under-test socket 930.

The test arrangement 900 may comprise an electrical connection between the daughter board 970 and the carrier structure 910 using an electrical connector 974 (e.g. using a connector (e.g. an array connector) for digital/power signals and optionally also for high frequency signals or microwave signals, e.g. for IF RF signals). The electrical connector 974 may be configured to establish an electrical connection between the load board and the device under test 940 (e.g. by electrically connecting the carrier structure 910 with the device under test 940. The electrical connector 974 may be configured to transmit IF RF signals or microwave signals. A high performance electrical connector 974 such as a high performance array connector may be provided.

The daughter board 970 may comprise one or more mounted electrical connectors 976 that are electrically connected (or connectable) to the device-under-test socket 930 (e.g., to contacts of the device-under-test socket 930 that are configured to establish an electrical connection with the device under test 940). Alternatively, the one or more electrical connectors 976 may be configured to establish an electrical connection to an automated test equipment, or to external signal generation and/or measurement equipment which may, for example, be controlled by the automated test equipment. In the example shown in FIG. 9, the electrical connector 976 is a coaxial connector. The mounted electrical connector 976 may be provided in addition or as an alternative to the electrical connector 974.

The device-under-test socket 930 and/or the daughter board 970 may comprise one or more coaxial pogo pins (e.g., spring pins). In the example shown in FIG. 9, the device-under-test socket 930 comprises a socket pogo pin 978. The coaxial pogo pins allows establishing an electrical contact between with the device under test 940 (e.g., when the device under test is pushed into the device-under-test socket 930, which may cause the socket pogo pin 978 to at least partially retract).

To conclude, the test arrangement 900 allows for the testing of one or more devices under test, which may be placed in the device-under-test socket 930. The device under test may be placed at a spacing from the carrier structure 910, wherein the daughter board 970 is in between the carrier structure (e.g. load board) 910 and the device-under-test socket. The daughter board may, for example, be a printed circuit board and may, for example, comprise electrical routes which establish an electrical connection between connectors, that connect the carrier structure and the daughter board and the device under test socket. Accordingly, the device under test socket may, for example, be attached (or connected) directly (or closely) to the daughter board using a conventional technology, and the daughter board may be coupled to the carrier structure (e.g. load board) using a “long range” connection, which is suitable to cover a spacing, for example, in a range between 5 mm and 50 mm. Accordingly, a proper placement of the device under test can be achieved with good mechanical stability and good electrical characteristics of the connection between the support structure and the device under test.

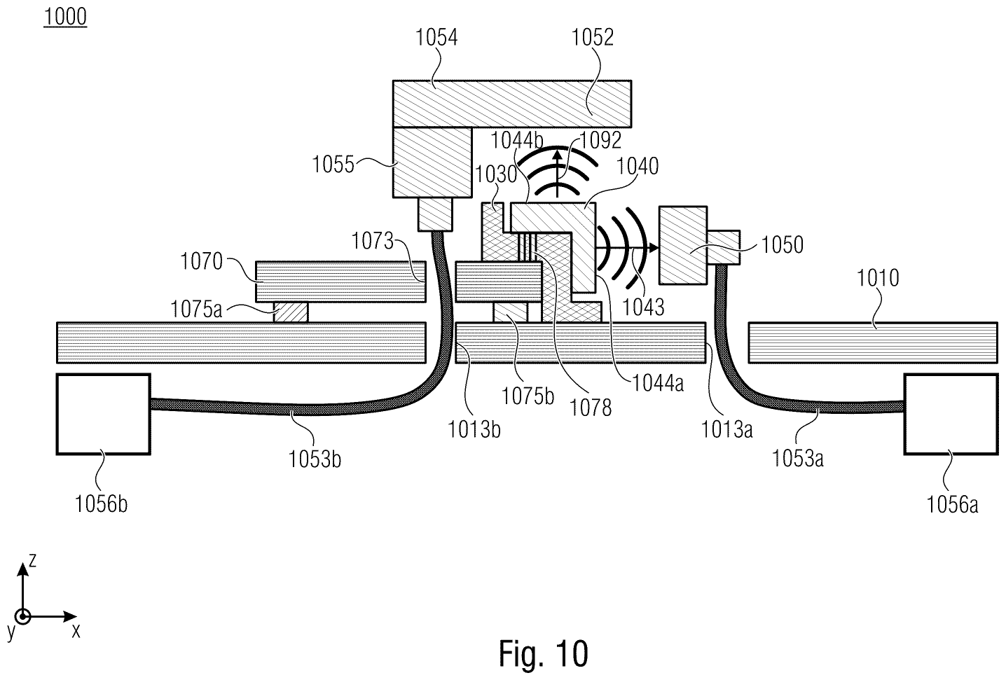

FIG. 10 shows schematic cross sectional view of another example of a test arrangement 1000 with a device under test 1040.

The test arrangement comprises a first antenna or antenna structure 1050 configured to receive a signal radiated from a first outer surface 1044a of the angled device 1140 under test and/or configured to emit a signal to be received at the first outer surface 1044a of the angled device under test1040. In the example shown in FIG. 10, an aperture of the first antenna or antenna structure 1050 is arranged at a distance from the first outer surface 1044a of the angled device under test 1040, such that a surface normal 1043 of the first outer surface 1044a of the angled device under test extends through the aperture of the first antenna or antenna structure 1050. Alternatively, the first antenna or antenna structure 1050 may be arranged at a different orientation and/or at a different distance (e.g., close or abutting against the first outer surface 1044a). There may, optionally, be a pusher (for pushing the device under test into the device under test socket) in between the first outer surface 1044a and the first antenna or antenna structure 1050.

The first antenna or antenna structure 1050 is, for example, mounted to have a fixed position with respect to a device-under-test socket 1030. The first antenna or antenna structure 1050 may be mounted to a carrier structure 1010. The signal transmission between the first antenna or antenna structure 1044a may be performed in a direction parallel to a surface of the carrier structure 1010 (e.g., due to the positioning of the angled device under test 1140 in the device-under-test socket 1140) such that the angled device under test 1140 can be inserted into the device-under-test socket 1030 from above (e.g., in a direction perpendicular, or at least approximately perpendicular, to the surface of the carrier structure 1010) without requiring removal of the first antenna or antenna structure 1050.

The first antenna or antenna structure 1050 may comprise (or be part of) a housing with a waveguide, wherein an aperture of the waveguide forms (or is part of, or transitions into) the aperture of the first antenna or antenna structure 1050. The waveguide of the first antenna or antenna structure 1050 may, for example, be coupled to a coaxial connector or to a coaxial cable.

The first antenna or antenna structure 1050 may be connected (or connectable) with a signal source and/or with a signal receiver 1056a. In the example shown in FIG. 10, the first antenna or antenna structure 1050 comprises a first coaxial cable 1053a connected (or connectable) with the signal source and/or with a signal receiver 1056a. However, any other form of electrical signal transmission (like a waveguide connection or a blind mating waveguide connection) may be used instead.

The first antenna or antenna structure 1050 may be configured to be connected (e.g., via the first coaxial cable 1053a) with the first signal source and/or with a signal receiver 1056a via a blind-mating microwave connection (e.g. via a blind mating waveguide connection) when the first antenna or antenna structure 1050 is placed in an operating position (e.g., by a handler). In this case, the first antenna or antenna structure may, for example, be moved by a handler.

The test arrangement 1000 may comprise a second antenna or antenna structure 1152 (as exemplarily depicted in FIG. 10) (e.g. a single aperture antenna (e.g. dual linear polarized or circular polarized)) configured to receive a signal radiated from a second outer surface 1044b of the angled device under test 1040 and/or to emit a signal to be received at the second outer surface 1044b of the angled device under test 1040 (e.g., at least when the second antenna or antenna structure 1052 is placed at an operation position).

The second antenna or antenna structure 1052 and/or an antenna carrier structure 1054 (which may, for example, mechanically carry the antenna structure 1052 and comprise one or more feed lines which are coupled to the antenna or antenna structure 1052) is, for example, mechanically attached (or attachable) to an arm of a handler, such that the second antenna or antenna structure 1052 and/or the antenna carrier structure 1054 is moveable. The handler may be movable (e.g., detachable), e.g., in order to give access to the device-under-test socket 1030, for example, to allow insertion and/or removal of the device under test 1140. In the example shown in FIG. 10, the antenna structure 1052, or the antenna carrier structure 1054, is connected (or connectable) to a (e.g., blind-mating) microwave connection 1055. For example, the handler may move the antenna structure 1052 and the carrier structure, and may push the antenna carrier structure 1054 (which may comprise a connection structure, e.g. a hollow waveguide and/or a coaxial cable, and/or a microstrip line) towards the microwave connection, to thereby establish an electrical connection between the antenna an the microwave connection 1055. The microwave connection 1055 is electrically connected to a second signal source and/or with a signal receiver 1056b.

It is noted that the test arrangement 1000 shown in FIG. 10 has two separate signal sources and/or signal receivers 1056a, b which are coupled to the different antenna structures 1050,1052. However, the test arrangement 1000 may have a common (e.g., single) signal source and/or signal receiver, which may be connected to the first and second antenna or antenna structure 1050, 1052 by separate or common electrical connections (such as coaxial cables and/or hollow waveguides).

An aperture of the second antenna or antenna structure 1052 may be arranged at a distance from the second outer surface 1044b of the angled device under test 1040 such that a surface normal 1092 of the second outer surface 1044b of the angled device under test 1040 extends through the aperture of the second antenna or antenna structure 1040 (e.g., at least when the second antenna or antenna structure 1052 is placed at an operation position).

In the example shown in FIG. 10, the first and second antenna or antenna structures 1050, 1052 are arranged at a distance from the first and second outer surfaces 1044a, b. However, in some cases, at least one of the first and second antenna or antenna structures 1050, 1052 may be arranged so as to almost or fully contact the respective one of the first and second outer surface 1044a, b. To this end, at least one of the first and second antenna or antenna structure 1050, 1052 may comprise a cover or spacer over the respective aperture, which comprises a material that is at least partially transparent for operation frequencies of the device under test 1040.

The second antenna or antenna structure 1052 may comprise (or be part of) a housing with a waveguide, wherein an aperture of the waveguide forms (or is part of) the aperture of the second antenna or antenna structure 1052. The waveguide of the second antenna or antenna structure 1052 or a waveguide of the microwave connection 1055 may be coupled to a coaxial connector.

The test arrangement 1000 comprises the first coaxial cable 1053a coupled or coupleable to the coaxial connector of (or associated with) the first antenna or antenna structure 1050. The test arrangement 1000 further comprises the second coaxial cable 1053b coupled or coupleable to the microwave connection 1055 of (or associated with) the second antenna or antenna structure 1052. Alternatively, the test arrangement 1000 may comprise a different device for signal transmission or any other number of coaxial cables.

In the example shown in FIG. 10, the carrier structure 1010 comprises a first carrier opening 1013a configured to receive the first coaxial cable 1053a and a second carrier opening 1013b configured to receive the second coaxial cable 1053b. The test arrangement 1000 comprises a daughter board 1070 with a board opening 1073 configured to receive the second coaxial cable 1053b. The first and second coaxial cables 1053a, b can therefore be partially arranged on a side of the carrier structure 1010 opposite of the device-under-test socket 1030 (e.g., below the carrier structure 1010 as depicted in FIG. 10). Therefore, an influence on signal transmission between the device under test 1030 and the first and/or second antenna or antenna structures 1050, 1052 that may be caused by the first and second coaxial cables 1053a, b and other devices such as the first and/or second signal sources and/or signal receivers 1056a, b connected thereto is reduced. Furthermore, arranging the first and/or second signal sources and/or signal receivers 1056a, b on the opposite side of the carrier structure 1010 allows for a shorter length the first and second coaxial cables 1053a, b, which improves signal quality.

At least one of the first and second coaxial cable 1053a, b may be arranged movable inside (e.g. entirely removable from) the respective board openings 1013a, 1013b, 1073, e.g., by virtue of a diameter of the respective opening being large enough to allow for movement of the respective first or second coaxial cable 1053a, b. Alternatively, at least one of the first and second coaxial cable 1053a, b may be fixedly held by the respective board openings 1013a, 1013b, 1073 (e.g., by frictional engagement).

Alternatively, the carrier structure 1010 may have no board opening for the first and/or second coaxial cable 1053a, b, wherein the first and/or second coaxial cable 1053a, b are entirely arranged on the same side of the carrier structure 1010 as the device-under-test socket 1040 (e.g., above the carrier structure 1010 shown in FIG. 10). Alternatively or additionally, the daughter board 1070 may have no board opening for the second coaxial cable 1053b.

The daughter board 1070 may be any daughter board as described herein (e.g., daughter board 970). In the example shown in FIG. 10, the daughter board 1070 comprises spacers or stacking connectors 1075a, b, wherein, for example, one or more electrical connectors may be integrated into one of the spacers or staking connectors 1075a, 1075b, or wherein one or more electrical connectors may take the place of one or more of the spacers or stacking connectors 1075a, 1075b. At least one of the stacking connectors may be configured to transmit signals (e.g., digital signals) and/or electrical power. To this end, at least one of the spacers or stacking connectors 1075a, b, may comprise an electrical connector (e.g., electrical connector 974).

The device-under-test socket 1030 comprises socket pogo pins 1078. The socket pogo pins 1078 may be configured to establish an electrical connection between the device-under-test socket 1030 and an inner surface of the device under test 1140.

The socket pogo pins 1078 may be retractable into the device-under-test socket 1030 and/or into the daughter board 1070.

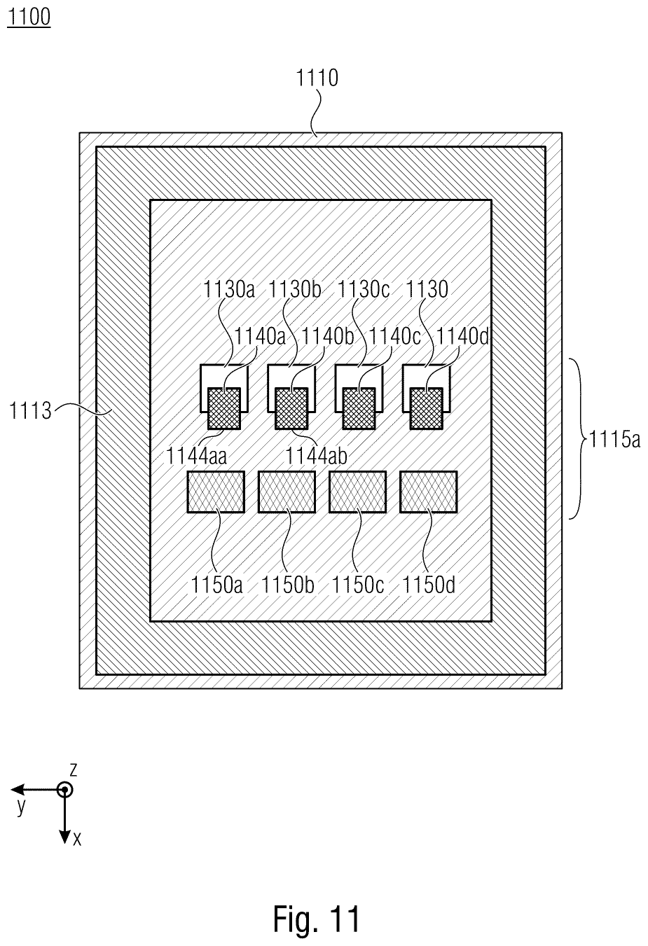

FIG. 11 shows a schematic top view of an another example of a test arrangement 1100 with a plurality of devices under test 1140a, b, c, d. The test arrangement 1100 comprises a carrier structure 1110 (which may comprise any carrier structure described herein) (e.g., a printed circuit board test fixture or loadboard) and four (e.g. four equal) device-under-test sockets 1130a, b, c, d (which may be any device-under-test socket described herein). However, the test arrangement 1100 may comprise any other amount of device-under-test sockets (e.g., two, three, five, six, or more). The plurality of devices under test 1140a-d may be arranged in a row 1115a, as depicted in FIG. 11. The test arrangement 1100 allows testing a plurality of devices under test 1140a-d and therefore may improve test efficiency. Testing may be performed simultaneously, e.g., in order to increase time efficiency. Alternatively, testing may be performed in succession in order to reduce crosstalk between the devices under test 1140a-d.

The device-under-test sockets 1130a-d are arranged to position respective angled devices under test 1140a-d such that respective first outer surfaces (in FIG. 11, a first outer surface 1144a of the device under test 1140a is shown as an example) of the respective angled devices under test are aligned in the same direction (in FIG. 11 in positive x-direction). The alignment in the same direction allows a more densely packed arrangement of the device-under-test sockets 1130a-d.

The test arrangement 1100 comprises four first antennas or antenna structures 1150a, b, c, d (which may be any first antenna or antenna structure described herein) (e.g., side measurement antennas). However, the test arrangement 1100 may comprise any other number of first antennas or antenna structures 1150a-d, e.g., the same number as device-under-test sockets 1130a-d. In the example shown in FIG. 11, each one of the device-under-test sockets 1130a-d is assigned a respective one of the first antennas or antenna structures 1150a-d. Each one of the first antennas or antenna structures 1150a-d is configured to receive a signal radiated from the first outer surface of the assigned (respective) angled device under test 1140a-d and/or configured to emit a signal to be received at the first outer surface of the assigned (respective) angled device under test 1140a-d.

An aperture of at least one of the first antennas or antenna structures 1150a-d may be arranged at a distance from the respective ones of the first outer surface of the angled devices under test 1140a-d, such that a surface normal of the first outer surface of the respective angled device under test 1140a-d extends through the aperture of the respective one of the first antennas or antenna structures 1150a-d.

In the example shown in FIG. 11, the test arrangement 1100 does not comprise second antennas or antenna structures for the sake of not obscuring the devices under test 1140a-d. However, the test arrangement 1100 may comprise only first antennas or antenna structures (i.e. without second antennas or antenna structures), only second antennas or antenna structures (i.e. without first antennas or antenna structures), or first and second antennas or antenna structures.

The carrier structure 1110 may define a board limit 1113 (e.g., a handler docking plate limit), which defines a region (e.g., a rectangular frame) that encloses a region that supports mounting device-under-test sockets 1130a-d.

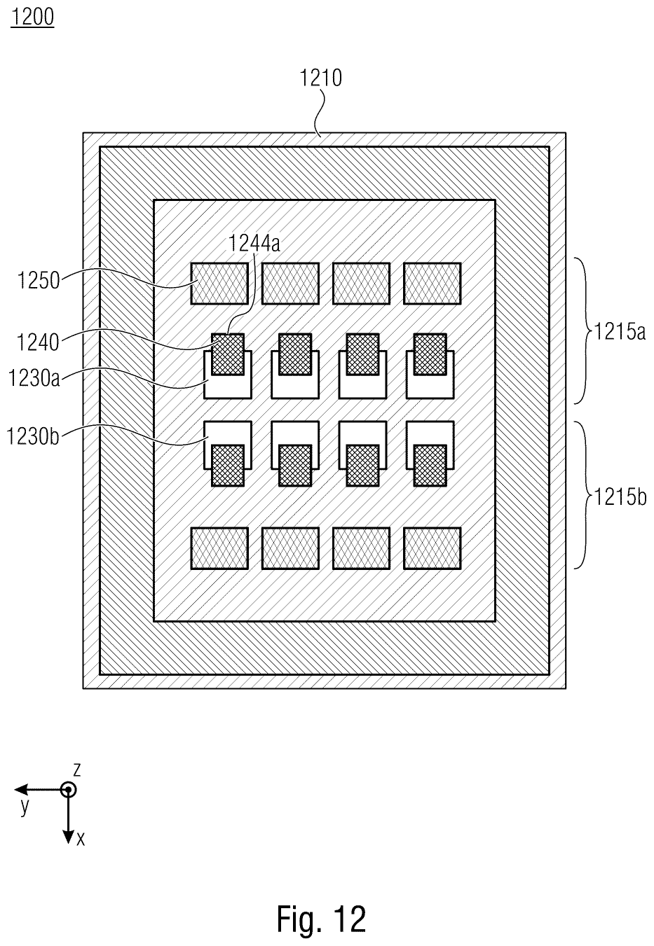

FIG. 12 shows a schematic top view of an another example of a test arrangement 1200 with a plurality of devices under test 1240. The test arrangement 1200 comprises a carrier structure 1210 (which may comprise any carrier structure described herein) (e.g., a printed circuit board test fixture or loadboard) and eight (e.g. eight equal) device-under-test sockets 1230 (which may be any device-under-test socket described herein). However, the test arrangement 1200 may comprise any other number of device-under-test sockets (e.g., two, three, five, six, or more).

At least two device-under-test sockets 1230 are arranged (e.g. back-to-back) to position respective angled devices under test 1240 such that respective first outer surfaces 1244aa of the respective angled devices under test are aligned in opposite (averted) directions. For the sake of visibility, in FIG. 12 only the left most device-under-test sockets 1230 are discussed and therefore provided with reference signs 1230a, b. But the same principle applies to the remaining device-under-test sockets 1230. A first device-under-test socket 1230a is configured to arrange a respective device under test 1240a such that its respective first outer surface 1244aa faces in a first direction (e.g., in FIG. 12 in a negative x-direction). A second device-under-test sockets 1230b is configured to arrange a respective device under test 1240b such that its respective first outer surface 1244ab faces in a second direction (e.g., in FIG. 12 in a positive x-direction) that is arranged opposite (e.g., anti-parallel) to the first direction. As a result, the first outer surfaces 1244aa, 1244ab of the devices under test 1240a, 1240b arranged in the first and second device-under-test sockets 1230a, b face opposite directions. Consequently, first antennas or antenna structures 1250a, 1250b assigned to the respective first and second device-under-test sockets 1230a, b may be arranged at opposite orientations. Furthermore, the first antennas or antenna structures 1250a, 1250b assigned to the respective first and second device-under-test sockets 1230a, b may be arranged such that the first and second device-under-test sockets 1230a, b are arranged between (e.g., sandwiched) the assigned first antennas or antenna structures 1250a, 1250b. Such an arrangement reduces a risk of cross talk between devices under test 1240a, 1240b coupled to the first and second device-under-test sockets 1230a, b.

The test arrangement 1200 comprises two rows (e.g. parallel rows) 1215a, b of device-under-test sockets 1230a, 1230b and associated first antennas 1250a, 1250b, wherein the device-under-test sockets 1230 are configured to carry respective angled devices under test 1240a, 1240b, wherein the at least two rows 1215a, b of device-under-test sockets 1240 are arranged (e.g. back-to-back; e.g. with sides of the device-under-test sockets 1230 where the first outer surfaces 1244a of the devices under test 1240 are located, averted with respect to each other) to position respective angled devices under test 1240a, 1240b such that respective first outer surfaces 1244aa, 1244ab of the respective angled devices under test 1240a, 1240b are aligned in opposite (averted) directions. Such an arrangement improves a compromise between reduction of crosstalk and increase of packing density.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A test arrangement for over-the-air testing an angled device under test, the test arrangement comprising:
a carrier structure; and
a device-under-test socket which is coupled to the carrier structure;
wherein the device-under-test socket is configured to establish an electrical contact with an inner surface of the angled device under test or with a connector which is arranged on the inner surface of the angled device under test.

2. The test arrangement of claim 1,
wherein the device-under-test socket is configured to position the angled device-under-test
such that a first outer surface of the angled device under test is spaced apart from a surface of the carrier structure, and
such that a surface normal of the first outer surface of the angled device-under-test is parallel, within a tolerance of +/−15 degrees, to a surface of the carrier structure.

3. The test arrangement of claim 1,
wherein the device-under-test socket is configured to position the angled device-under-test
such that a second outer surface of the angled device under test is facing away from the carrier structure, and
such that a surface normal of the second outer surface of the angled device-under-test is perpendicular, within a tolerance of +/−15 degrees, to the surface of the carrier structure.

4. The test arrangement according to claim 2,
wherein an area of the carrier structure which is adjacent to the first outer surface of the angled device-under-test is free from power planes and free from ground planes and free from metallization.

5. The test arrangement according to claim 2, further comprising:
an absorber material;
wherein the absorber material is arranged on the carrier structure in an area which is adjacent to the first outer surface of the angled device-under-test.

6. The test arrangement according to claim 2,
wherein the device-under-test socket is configured to position the angled device-under-test such that a spacing between the first outer surface of the angled device under test and the carrier structure is at least 2 wavelengths at a lowest frequency of operation of the angled device under test.

7. The test arrangement according to claim 1, further comprising:
a daughter board, and
a load board;
wherein the daughter board is mounted to the carrier structure;
wherein there is a spacing between the daughter board and the load board; and
wherein the device-under-test socket is attached to the daughter board.

8. The test arrangement according to claim 2, further comprising:
a first antenna structure,
wherein the first antenna structure is configured to receive a signal radiated from the first outer surface of the angled device under test and/or to emit a signal to be received at the first outer surface of the angled device;
wherein an aperture of the first antenna structure is arranged at a distance from the first outer surface of the angled device under test, such that a surface normal of the first outer surface of the angled device under test extends through the aperture of the first antenna structure.

9. The test arrangement according to claim 2, further comprising:
a first antenna structure, and
a handler;
wherein the first antenna structure is configured to receive a signal radiated from the first outer surface of the angled device under test and/or to emit a signal to be received at the first outer surface of the angled device;
wherein the first antenna structure is mechanically attached to an arm of the handler, such that the first antenna structure is moveable.

10. The test arrangement according to claim 9, further comprising:
a signal source or a signal receiver;
wherein the first antenna structure is connected with the signal source or with the signal receiver via a blind-mating microwave connection when the handler has placed the first antenna structure in an operating position.

11. The test arrangement according to claim 3, further comprising:
a second antenna structure;
wherein the second antenna structure is configured to receive a signal radiated from the second outer surface of the angled device under test and/or to emit a signal to be received at the second outer surface of the angled device under test;
wherein an aperture of the second antenna structure is arranged at a distance from the second outer surface of the angled device under test such that a surface normal of the second outer surface of the angled device under test extends through the aperture of the second antenna structure.

12. The test arrangement according to claim 3, further comprising:
a second antenna structure; and
a handler;
wherein the second antenna structure is configured to receive a signal radiated from the second outer surface of the angled device under test and/or to emit a signal to be received at the second outer surface of the angled device under test;
wherein the second antenna structure is mechanically attached to an arm of the handler, such that the second antenna structure is moveable.

13. The test arrangement according to claim 3, further comprising:
a second antenna structure, and
a pusher;
wherein the pusher is configured to push the angled device under test into the device-under-test socket;
wherein the second antenna structure is configured to receive a signal radiated from the second outer surface of the angled device under test and/or to emit a signal to be received at the second outer surface of the angled device under test;
wherein the second antenna structure is part of the pusher, or
wherein the second antenna structure is configured to be moveable together with the pusher.

14. The test arrangement according to claim 3,
wherein the device-under-test socket is arranged such that a second inner surface of the angled device under test, which is opposite to the second outer surface of the angled device under test, is spaced from the carrier structure by at least 10 mm.

15. The test arrangement according to claim 3,
wherein the device-under-test socket comprises a socket height of at least 10 mm, such that a second inner surface of the angled device under test, which is opposite to the second outer surface of the angled device under test, is spaced from the carrier structure by at least 10 mm.

16. The test arrangement according to claim 1, further comprising:
an extender structure;
wherein the extender structure is arranged between the carrier structure and the device-under-test socket.

17. The test arrangement according to claim 16,
wherein the extender structure comprises an extender assembly,
wherein the extender assembly comprises one or more coaxial pogo pins, in order to establish an electrical connection between the carrier structure and the angled device under test.

18. The test arrangement according to claim 1,
wherein the test arrangement comprises at least two device-under-test sockets configured to carry respective angled devices under test,
wherein the at least two device-under-test sockets are arranged to position respective angled devices under test such that respective first outer surfaces of the respective angled devices under test are aligned in opposite directions.

19. The test arrangement according to claim 1,
wherein the test arrangement comprises at least two rows of device-under-test sockets,
wherein the device-under-test sockets are configured to carry respective angled devices under test,
wherein the at least two rows of device-under-test sockets are arranged to position respective angled devices under test such that respective first outer surfaces of the respective angled devices under test are aligned in opposite directions.

20. A test arrangement for over-the-air testing an angled device under test, comprising:
a carrier structure;
a device-under-test socket which is coupled to the carrier structure,
wherein the device-under-test socket is configured to establish an electrical contact with an inner surface of the angled device under test or with a connector which is arranged on the inner surface of the angled device under test, and
wherein the device-under-test socket is configured to position the angled device-under-test
such that a first outer surface of the angled device under test is spaced apart from a surface of the loadboard, and
such that a surface normal of the first outer surface of the angled device-under-test is parallel, within a tolerance of +/−15 degrees, to the surface of the loadboard, and
such that a second outer surface of the angled device under test is facing away from the loadboard, and
such that a surface normal of the second outer surface of the angled device-under-test is perpendicular, within a tolerance of +/−15 degrees, to the surface of the load board.
